(19) United States
(12) Patent Application Publication
(10) Pub. No.: US 2024/0191029 A1
(43) Pub. Date: Jun. 13, 2024

(54) HEAT-CURABLE IMIDE RESIN COMPOSITION, AND UNCURED RESIN FILM, CURED RESIN FILM, PREPREG, SUBSTRATE, ADHESIVE AND SEMICONDUCTOR ENCAPSULATION MATERIAL USING SAME

(71) Applicant: Shin-Etsu Chemical Co., Ltd., Tokyo (JP)

(72) Inventors: Masayuki IWASAKI, Annaka-shi (JP); Shinsuke YAMAGUCHI, Annaka-shi (JP); Yoshihiro TSUTSUMI, Annaka-shi (JP); Rina SASAHARA, Annaka-shi (JP)

(73) Assignee: Shin-Etsu Chemical Co., Ltd., Tokyo (JP)

(21) Appl. No.: 18/522,408

(22) Filed: Nov. 29, 2023

(30) Foreign Application Priority Data
Nov. 30, 2022 (JP) 2022-191212

(51) Int. Cl. C08G 73/10; C08J 5/18; C08J 5/24; C09D 179/08; C09J 179/08

(52) U.S. Cl. CPC C08G 73/1071; C08G 73/1032; C08J 5/18; C08J 5/244; C09D 179/08; C09J 179/08; C08J 2379/08

(57) ABSTRACT

Provided is a resin composition capable of being turned into a cured product having an excellent dielectric property as indicated by a low dielectric tangent at a high frequency, and also having an excellent heat resistance as indicated by a high Tg. The resin composition is a heat-curable imide resin composition containing:
(A) a modified imide compound represented by the following formula (1)

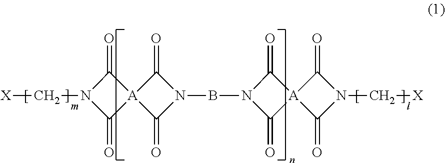

wherein A independently represents a tetravalent organic group having 4 to 200 carbon atoms; B independently represents a divalent organic group having 2 to 200 carbon atoms; n is 0 to 100; each of m and l is independently 0 to 18; X independently represents a carbon-carbon unsaturated bond-containing organic group; and
(B) a reaction promotor.

### BACKGROUND OF THE INVENTION

### Field of the Invention

The present invention relates to a heat-curable imide resin composition: and an uncured resin film, a cured resin film, a prepreg, a substrate, an adhesive and a semiconductor encapsulation material each using such composition.

### Background Art

In recent years, as electronic devices have become smaller and more highly advanced. finer and denser wirings are now required in multi-layered printed wiring boards. Further, since materials for high-frequency band uses are needed for the next generation, and reduction in transmission loss is crucial as a countermeasure for noises, there is now a demand to develop an insulating material superior in dielectric properties.

As an insulating material for use in a multi-layered printed wiring board, there are known epoxy resin compositions disclosed in JP-A-2007-254709 and JP-A-2007-254710 that contain. for example, an epoxy resin. a particular phenolic curing agent, a phenoxy resin, rubber particles, and a polyvinyl acetal resin. However, it has become clear that these materials are not satisfactory for high-frequency band uses as typified by the keyword “5G.” In this regard, JP-A-2011-132507 discloses that an epoxy resin composition containing an epoxy resin, an active ester compound, and a triazine-containing cresol novolac resin is effective in achieving a lower dielectric tangent; even this material needs to be more low-dielectric if used for high-frequency purposes.

Meanwhile, WO2016/114287 discloses that as a non-epoxy material, a resin film comprised of a resin composition having a long-chain alkyl group-containing bismaleimide resin and a curing agent is superior in dielectric properties. However, since this composition is technically a combination of a long-chain alkyl group-containing bismaleimide resin and a hard and low-molecular aromatic maleimide, it is very difficult to achieve a glass-transition temperature (Tg) as high as 100° C. or higher, which is required for substrate purposes.

Further, studies conducted in recent years have shown that in the case of the above long-chain alkyl group-containing bismaleimide resin, the resin design thereof has resulted in a trade-off correlation in that increasing Tg leads to poor dielectric properties, and improving dielectric properties leads to a decreased Tg.

In addition, JP-A-2017-119361 and JP-A-2019-104843 disclose polyimides whose raw materials are an aromatic tetracarboxylic anhydride, a dimer diamine derived from a dimer acid as a dimer of an unsaturated fatty acid such as oleic acid, and an alicyclic diamine. However, in the cases of these polyimides, since water will be produced due to cyclodehydration at the time of curing, if, for example, a metal foil is to be attached upon use, swelling may occur depending on use conditions.

### SUMMARY OF THE INVENTION

Thus, it is an object of the present invention to provide a heat-curable resin composition capable of being turned into a cured product having an excellent dielectric property as indicated by a low dielectric tangent at a high frequency, and also having an excellent heat resistance as indicated by a high Tg; and an uncured resin film, a cured resin film, a prepreg, a substrate, an adhesive and a semiconductor encapsulation material each using such composition.

The inventors of the present invention diligently conducted a series of studies to solve the above problems, and completed the invention by finding that the following heat-curable imide resin composition was able to achieve the abovementioned object.

<1>

A heat-curable imide resin composition comprising:
(A) a modified imide compound represented by the following formula (1)

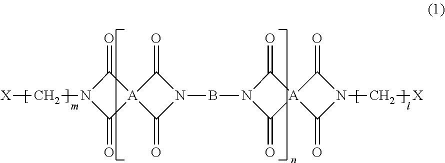

wherein A independently represents a tetravalent organic group having 4 to 200 carbon atoms; B independently represents a divalent organic group having 2 to 200 carbon atoms; n is 0 to 100; each of m and l is independently 0 to 18; X independently represents a carbon-carbon unsaturated bond-containing organic group expressed by the following formula (2)

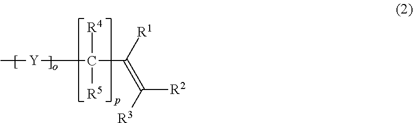

wherein each of R¹, R², R³, R⁴ and R⁵ independently represents a hydrogen atom, an alkyl group having 1 to 5 carbon atoms, or a (hetero)aryl group having 4 to 10 carbon atoms; each of o and p is independently 0 or 1; Y represents any one of the divalent organic groups expressed by the following structural formulae

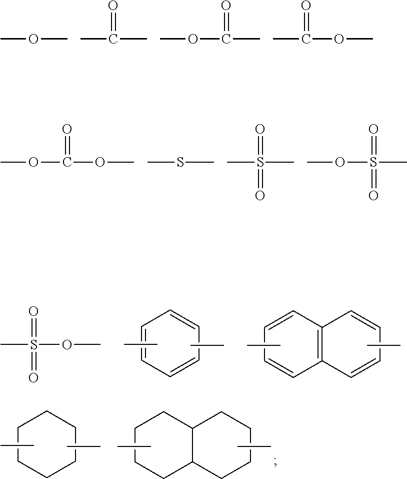

and
(B) a reaction promotor
   <2>

The heat-curable imide resin composition according to <1> wherein A in the formula (1) is any one of the tetravalent organic groups represented by the following structural formulae

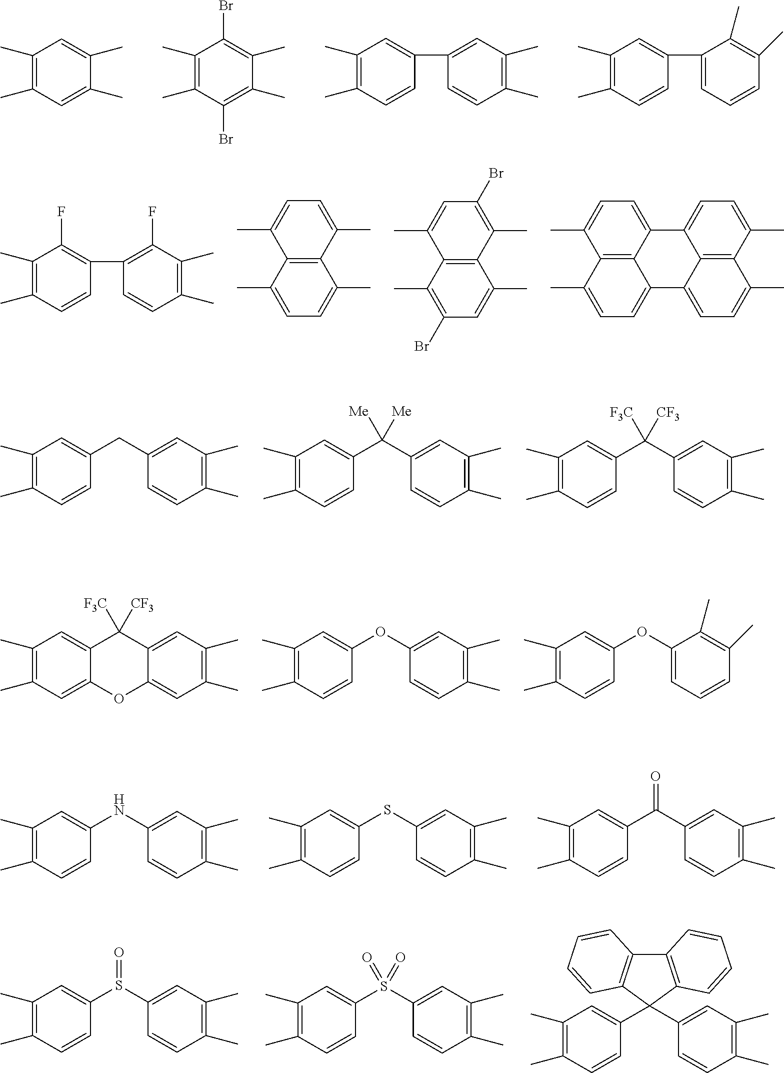

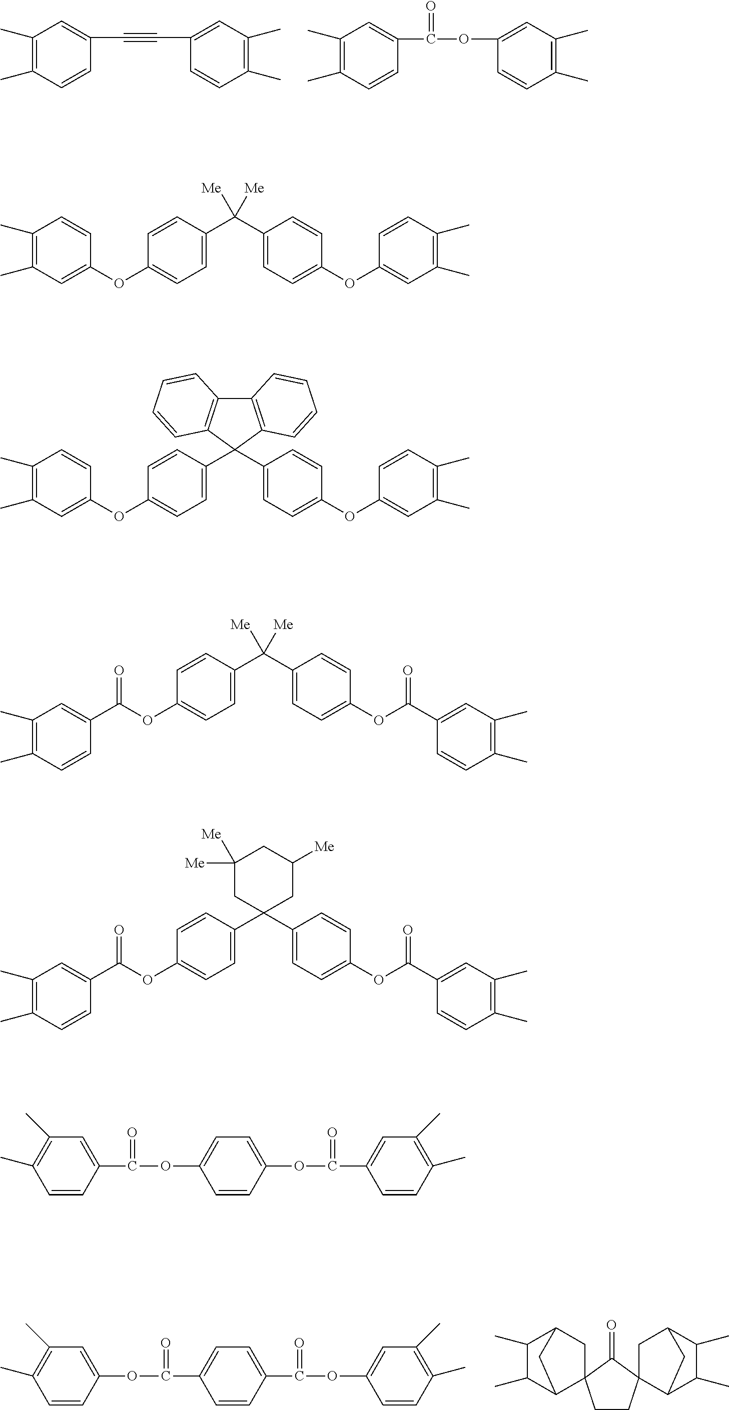

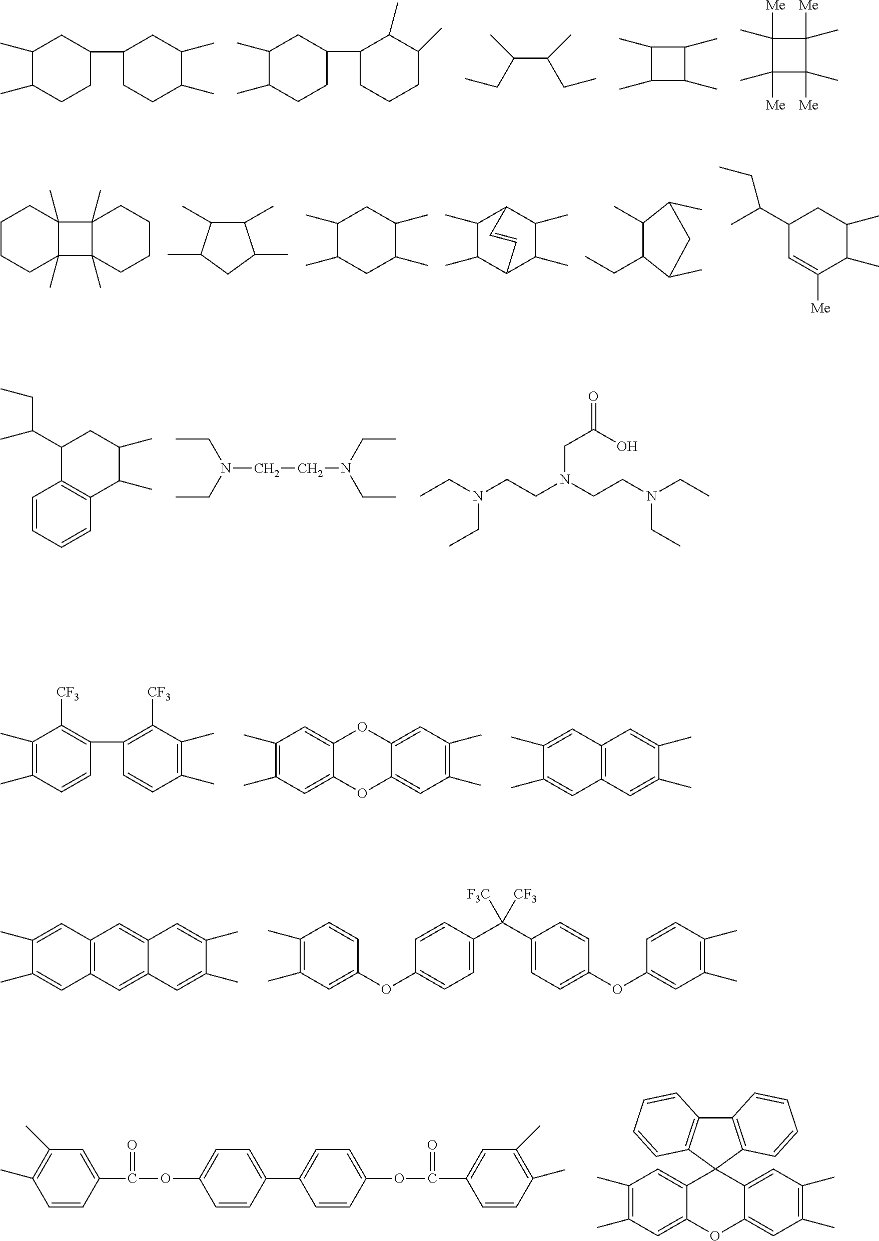

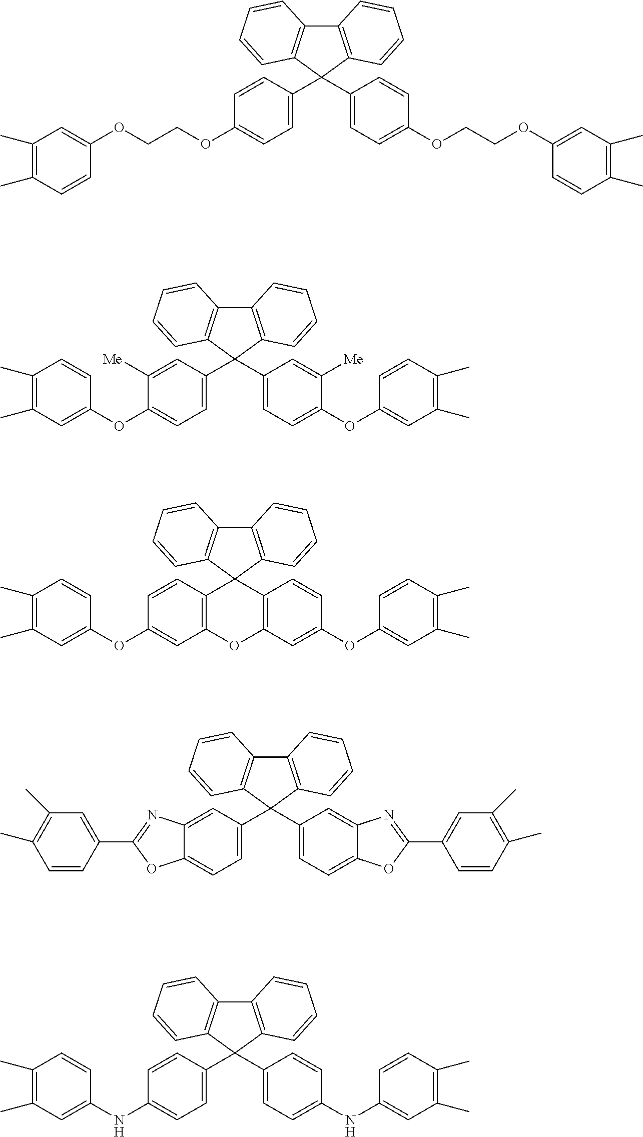

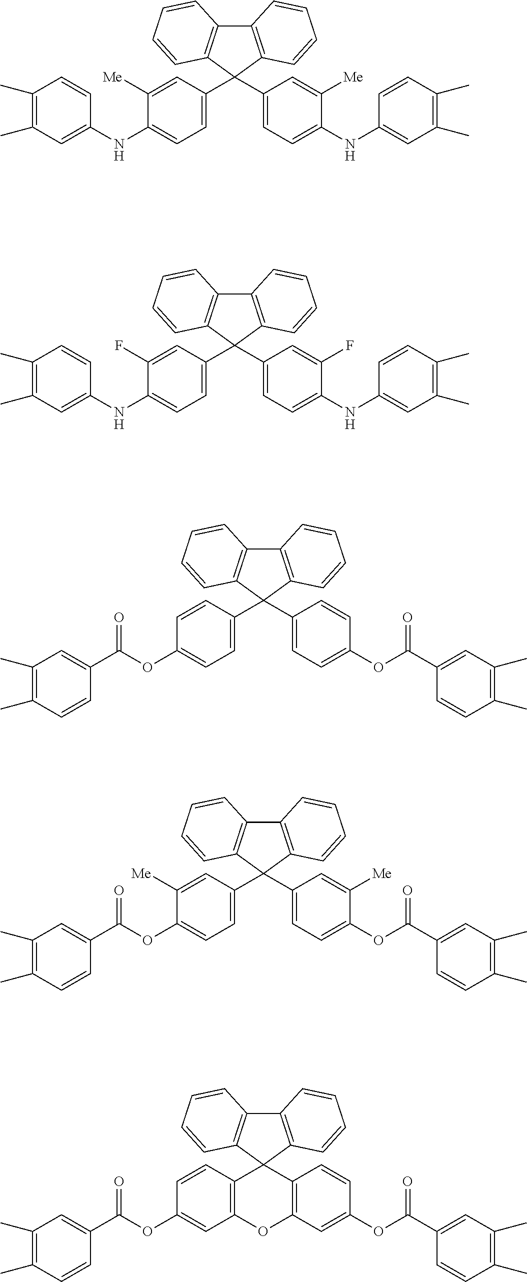

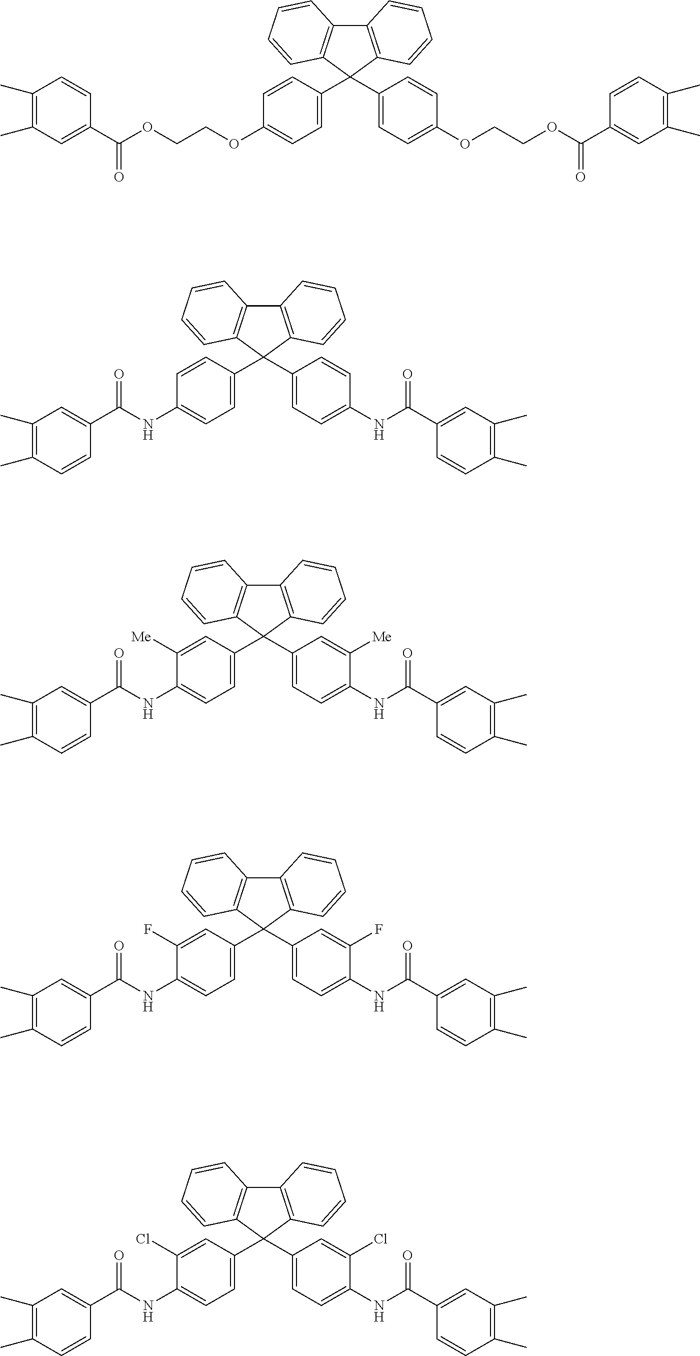

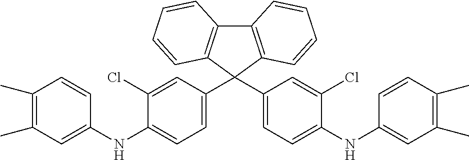

wherein bonds that are yet unbonded to substituent groups are to be bonded to carbonyl carbons forming cyclic imide structures in the formula (1).
   <3>

The heat-curable imide resin composition according to <1> or <2 wherein the modified imide compound of the formula (1) has a number average molecular weight of 200 to 80,000.

<4>

The heat-curable imide resin composition according to any one of <1> to <>, wherein the reaction promotor as the component (B) is a radical polymerization initiation catalyst, or an anionic polymerization initiation catalyst containing at least one of nitrogen atom and phosphorus atom.

<5>

An uncured resin film comprised of the heat-curable imide resin composition according to any one of <1> to <4>.

<6>

A cured resin film comprised of a cured product of the heat-curable imide resin composition according to any one of <1> to <4>.

<7>

A prepreg comprising the heat-curable imide resin composition according to any one of <1> to <4> and a fiber base material.

<8>

A substrate comprising the heat-curable imide resin composition according to any one of <1> to <4>.

<9>

An adhesive comprised of the heat-curable imide resin composition according to any one of <1> to <4>.

<10>

A semiconductor encapsulation material comprised of the heat-curable imide resin composition according to any one of <1> to <4>.

The heat-curable imide resin composition of the present invention can be turned into a cured product having an excellent dielectric property as indicated by a low dielectric tangent at a high frequency, and also having an excellent heat resistance as indicated by a high Tg. Particularly, as compared to a bismaleimide resin composition containing a compound which is the modified imide compound as the component (A) when the groups X on both ends thereof are maleimide groups, the composition of the present invention, when molded into the shape of a film or a substrate, is able to maintain a high glass-transition temperature and exhibit a low dielectric tangent, thus resulting in an excellent heat resistance and dielectric property.

### DETAILED DESCRIPTION OF THE INVENTION

The present invention is described in detail hereunder.

### (A) Modified Imide Compound

A component (A) used in the present invention is a modified imide compound represented by the following formula (1).

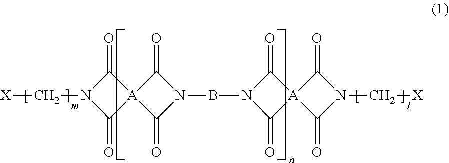

In the formula (1), A independently represents a tetravalent organic group having 4 to 200 carbon atoms. B independently represents a divalent organic group having 2 to 200 carbon atoms. n is 0 to 100. Each of m and l is independently 0 to 18. X independently represents a carbon-carbon unsaturated bond-containing organic group expressed by the following formula (2).

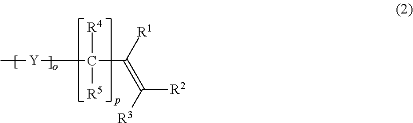

In the formula (2), each of R¹, R², R³, R⁴ and R⁵ independently represents a hydrogen atom, an alkyl group having 1 to 5 carbon atoms, or a (hetero)aryl group having 4 to 10 carbon atoms. Each of o and p is independently 0 or 1. Y represents any one of the divalent organic groups expressed by the following structural formulae.

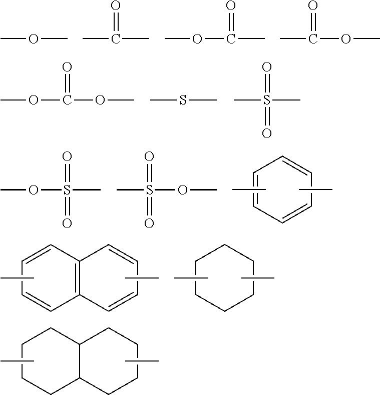

In the formula (1), A independently represents a tetravalent organic group having 4 to 200. preferably 4 to 100. more preferably 4 to 50 carbon atoms: particularly, it is preferred that A be any one of the tetravalent organic groups represented by the following structural formulae.

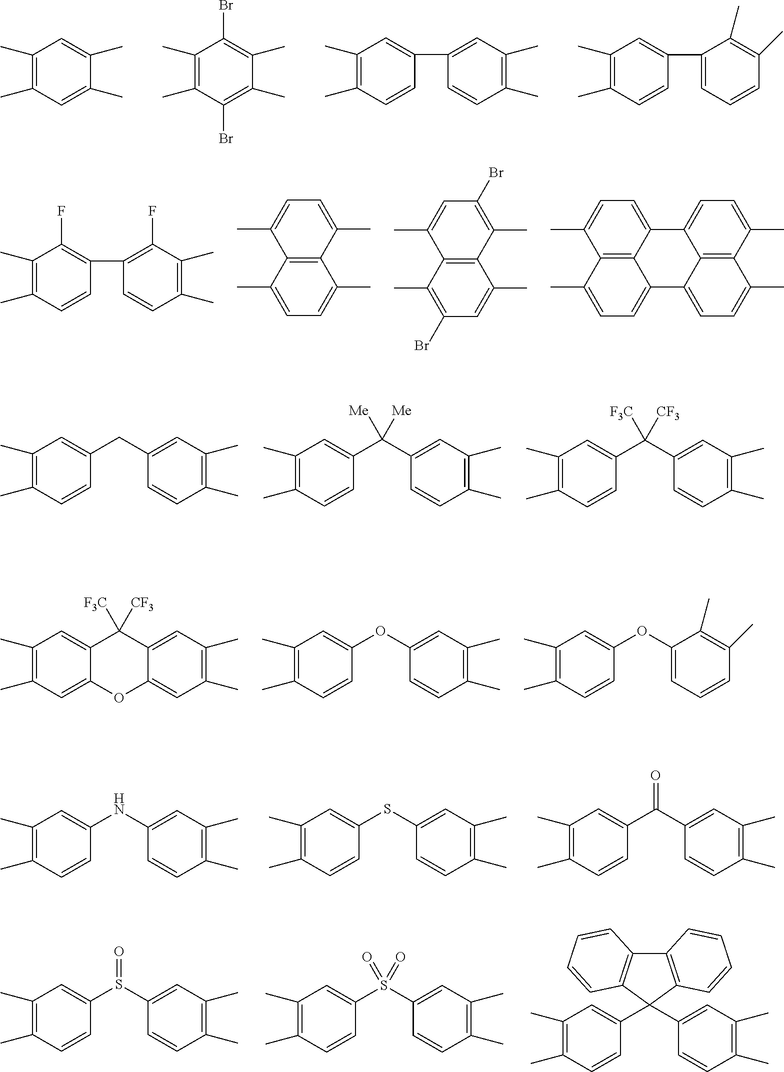

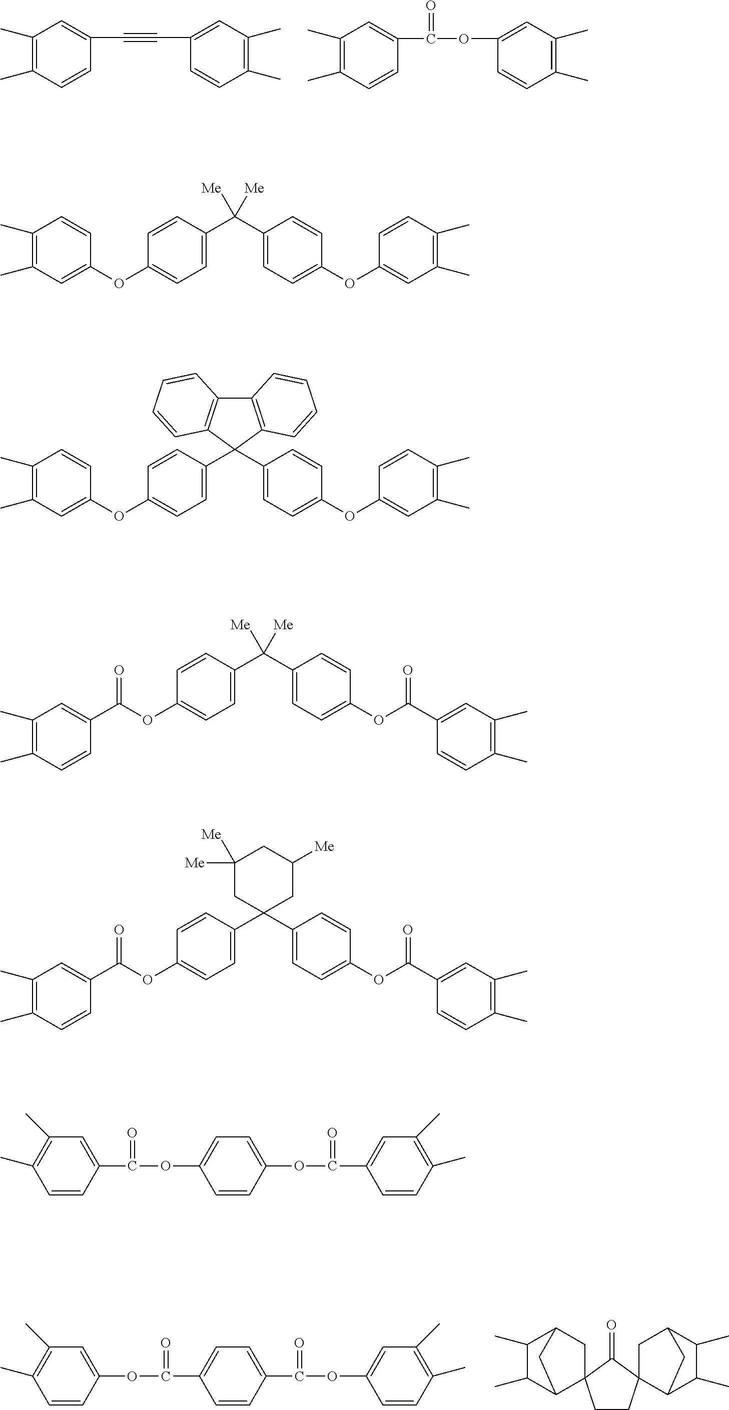

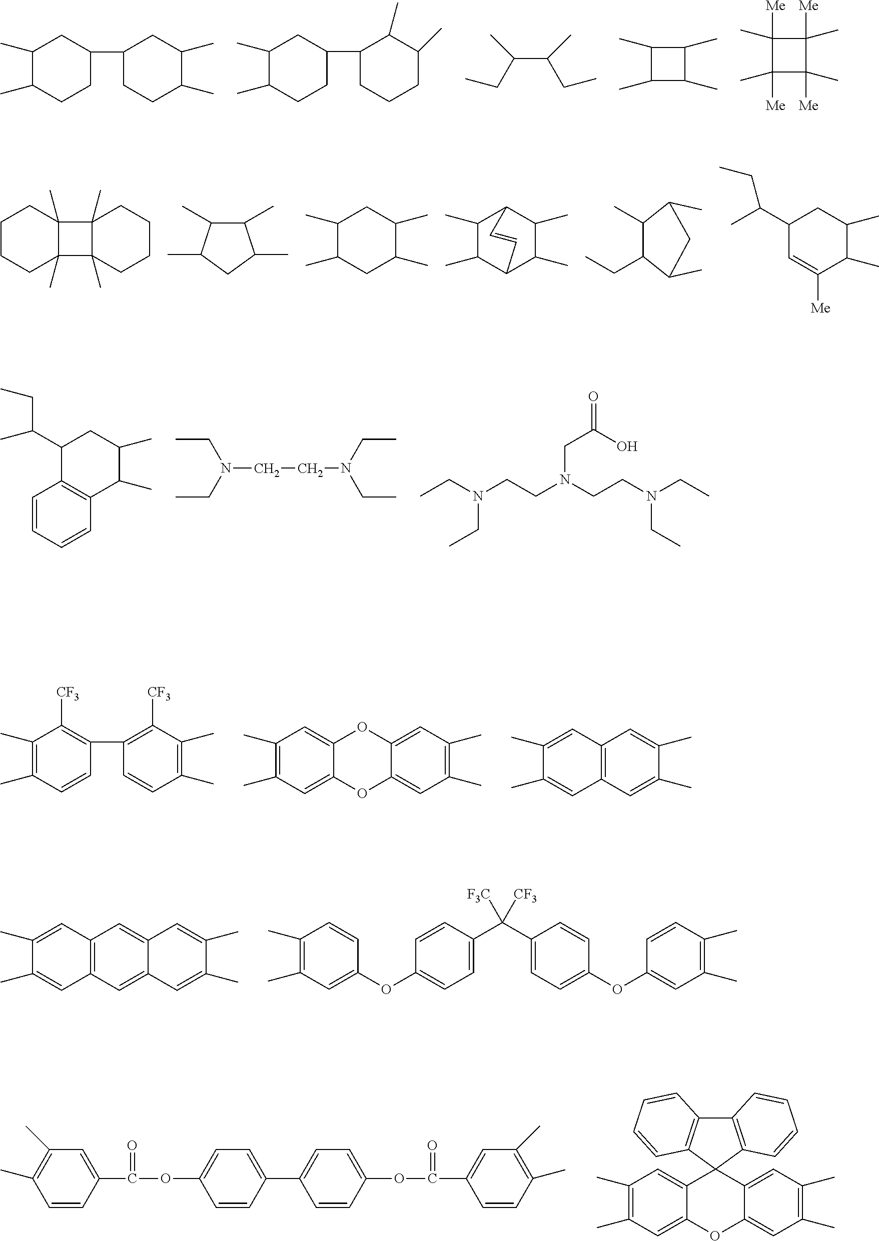

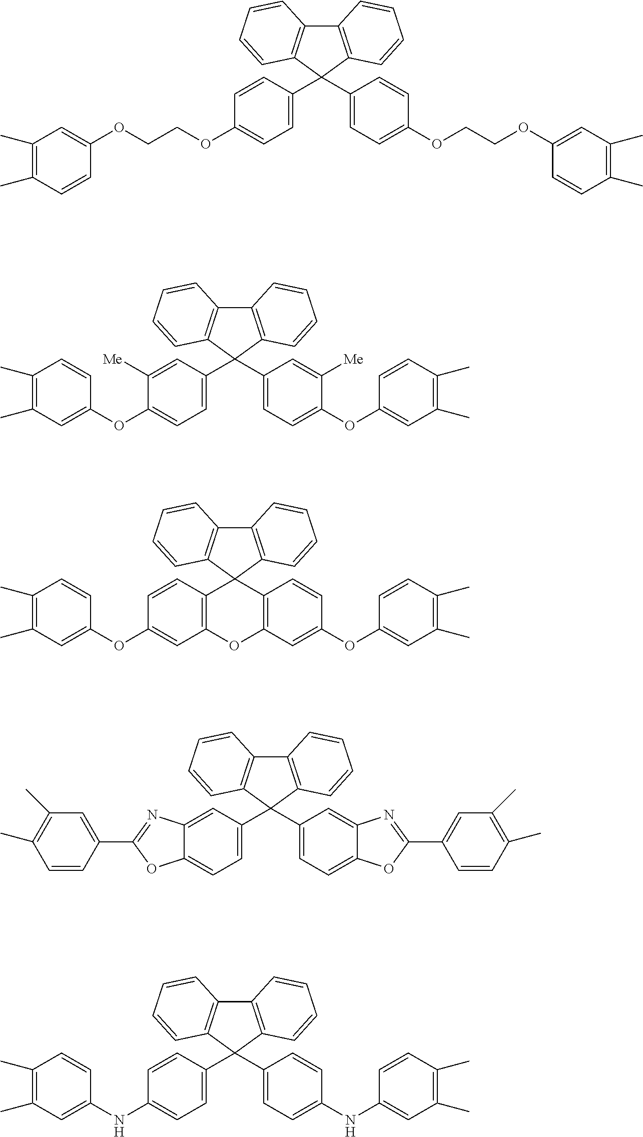

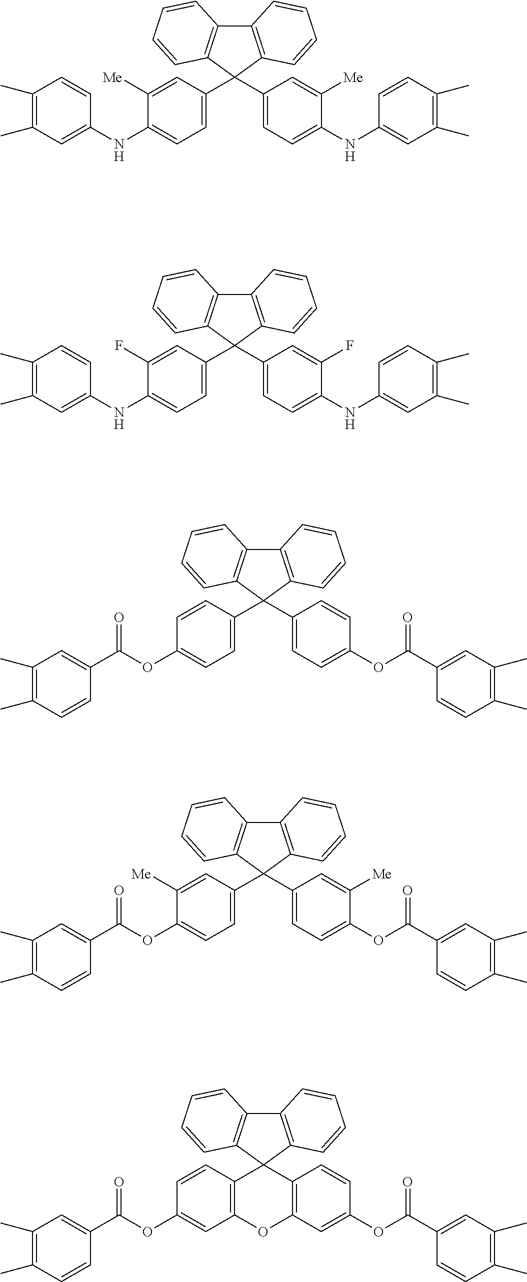

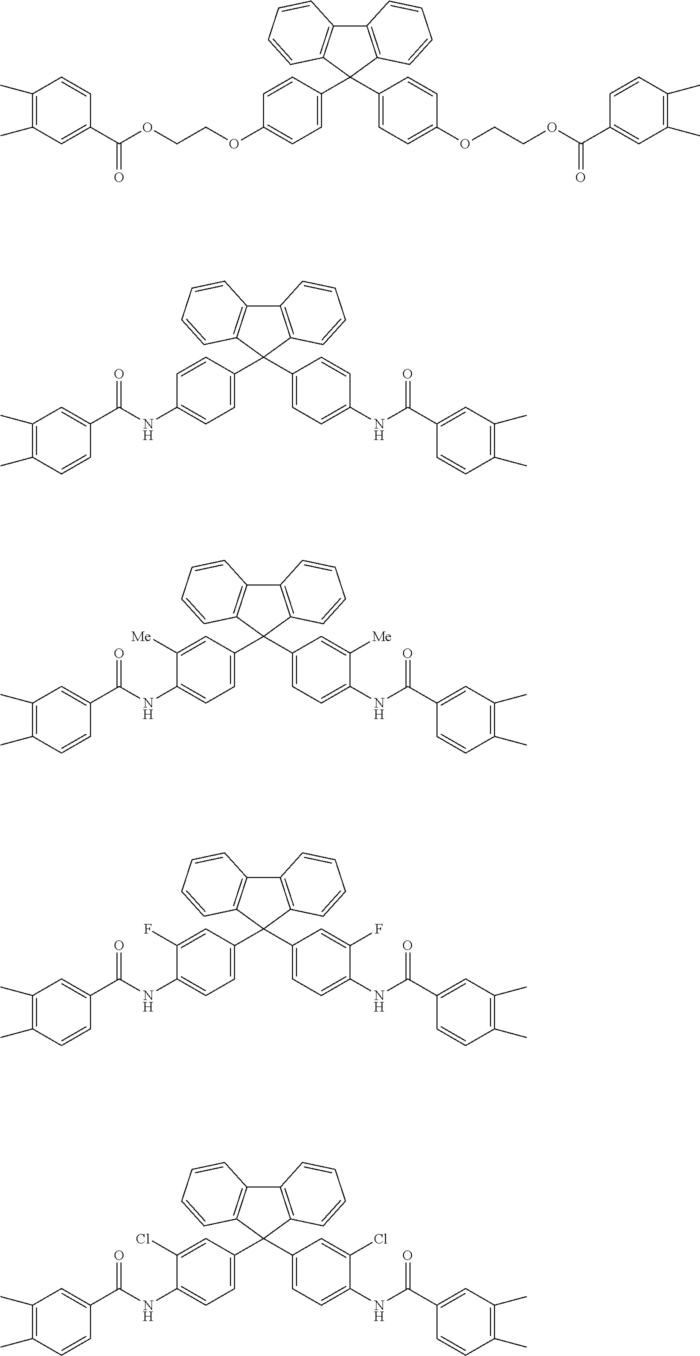

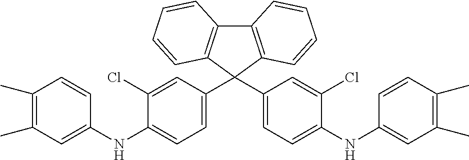

Bonds in the above structural formulae that are yet unbonded to substituent groups are to be bonded to carbonyl carbons forming cyclic imide structures in the formula (1).

Here, as for A in the formula (1), there may be used one or more kinds thereof.

In the formula (1), B independently represents a divalent organic group having 2 to 200, preferably 3 to 100, more preferably 6 to 50 carbon atoms. As the divalent organic group having 2 to 200 carbon atoms which is represented by B, there may be listed divalent organic groups obtained by eliminating two amino groups from diamines such as 1,10-diaminodecane, 1,12-diaminododecane, dimer diamine, 1,2-diamino-2-methylpropane, 1,2-diaminocyclohexane, 1,2-diaminopropane, 1,3-diaminopropane, 1,4-diaminobutane, 1,5-diaminopentane, 1,7-diaminoheptane, 1,8-diaminomenthane, 1,8-diaminooctane, 1,9-diaminononane, 3,3′-diamino-N-methyldipropylamine, diaminomaleonitrile, 1,3-diaminopentane, 9,10-diaminophenanthrene, 4,4″-diaminooctafluorobiphenyl, 3,5-diaminobenzoic acid, 3,7-diamino-2,8-dimethoxyfluorene, 4,4 -diaminobenzophenone, 3,4-diaminobenzophenone, 3,4-diaminotoluene, 2,6-diaminoanthraquinone, 2,6-diaminotoluene, 2,3-diaminotoluene, 1,8-diaminonaphthalene, 2,4-diaminotoluene, 2,5-diaminotoluene, 1,4-diaminoanthraquinone, 1,5-diaminoanthraquinone, 1,5-diaminonaphthalene, 1,2-diaminoanthraquinone, 2,4-cumenediamine, 1,3-bis(aminomethyl)benzene(m-xylylenediamine), 1,4-bis(aminomethyl)benzene(p-xylylenediamine), 1,3-bis(aminomethyl)cyclohexane, 2-chloro-1,4-diaminobenzene, 1,4-diamino-2,5-dichlorobenzene, 1,4-diamino-2,5-dimethylbenzene, 4,4 -diamino-2,2′-bistrifluoromethylbiphenyl, 1,2-bis(4-amino-3-chlorophenyl)ethane, bis(4-amino-3,5-dimethylphenyl)methane, bis(4-amino-3,5-diethylphenyl)methane, bis(4-amino-3-ethylphenyl)fluorene, 3,4-diaminobenzoic acid, 2,3-diaminonaphthalene, 2,3-diaminophenol, bis(4-amino-3-methylphenyl)methane, bis(4-amino-3-ethylphenyl)methane, 4,4′-diaminophenylsulfone, 3,3″-diaminophenylsulfone, bis(4-(4-aminophenoxy)phenyl)sulfone, bis(4-(3-aminophenoxy)phenyl)sulfone, 4,4′-oxydianiline, 4,4′-diaminodiphenylsulfide, 3,4′-oxydianiline, 2,2-bis(4-(4-aminophenoxy)phenyl)propane, 1,3-bis(4-aminophenoxy)benzene, 4,4 -bis(4-aminophenoxy)biphenyl, 4,4′-diamino-3,3′-dihydroxybiphenyl, 4,4′-diamino-3,3′-dimethylbiphenyl, 4,4 -diamino-3,3′-dimethoxy biphenyl, bisaniline M(1,3-bis[2-(4-aminophenyl)-2-propyl]benzene), bisaniline P (1,4-bis[2-(4-aminophenyl)-2-propyl]benzene), 9,9-bis(4-aminophenyl)fluorene, 9,9-bis[4-(4-aminophenoxy)phenyl]fluorene, o-tolidine sulfone, methylenebis(anthranilic acid), 1,3-bis(4-aminophenoxy)-2,2-dimethylpropane, 1,3-bis(4-aminophenoxy)propane, 1,4-bis(4-aminophenoxy)butane, 1,5-bis(4-aminophenoxy)pentane, 2,3,5,6-tetramethyl-1,4-phenylenediamine, 3,3′,5,5′-tetramethylbenzidine, 4,4′-diaminobenzanilide, 2,2-bis(4-aminophenyl)hexafluoropropane, polyoxyalkylenediamines (e.g., JEFFAMINE® D-230, D-400, D-2000 and D-4000 by Huntsman Corporation), bis(4-amino-3-methylcyclohexyl)methane, 1,2-bis(2-aminoethoxy)ethane, and 3(4),8(9)-bis(aminomethyl)tricyclo[5.2.1.0(2,6)]decane. Further, in terms of improving heat resistance, it is preferred that the divalent organic group having 2 to 200 carbon atoms, as represented by B, be an alicyclic structure- or aromatic ring-containing divalent organic group. For example, there may be listed the divalent organic groups represented by the following structural formulae.

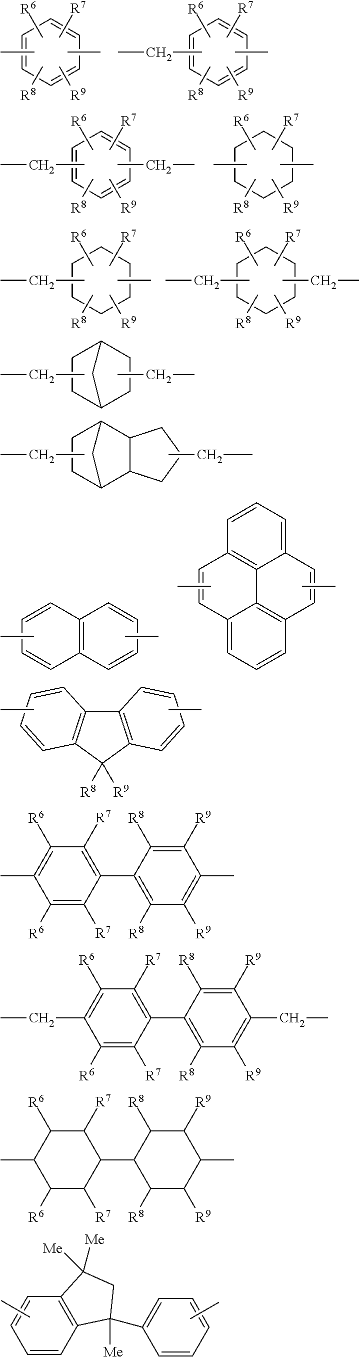

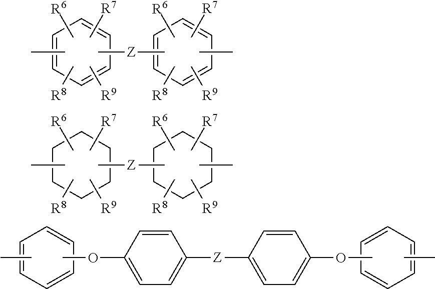

In the above formulae, each of R⁶, R⁷, R⁸ and R⁹ independently represents a hydrogen atom, an alkyl group having 1 to 5 carbon atoms, a methoxy group, a fluoro group, a chloro group, a bromo group, or a trifluoromethyl group. Z independently represents a divalent organic group selected from those expressed by the following formulae, a is a number of 0 to 6.

Here, as for B in the formula (1), there may be used one or more kinds thereof.

Further, in the formula (1), n is 0 to 100, preferably 0 to 90, more preferably 0 to 80.

There are no particular restrictions on the number average molecular weight (Mn) of the modified imide compound of the present invention; it is preferred that the compound of the invention have a number average molecular weight of 200 to 80,000, more preferably 200 to 70,000, even more preferably 200 to 60,000.

The number average molecular weight (Mn) mentioned in this specification refers to a number average molecular weight that is measured by GPC under the following conditions, using polystyrene as a reference substance.

### GPC Measurement Conditions

Developing solvent: Tetrahydrofuran
Flow rate: 0.6 mL/min
Column: TSK Guardcolumn Super H-L
   TSK gel Super H4000 (6.0 mm I.D.×15 cm×1)
   TSK gel Super H3000 (6.0 mm I.D.×15 cm×1)
   TSK gel Super H2000 (6.0 mm I.D.×15 cm×2)
(All manufactured by Tosoh Corporation)
Column temperature: 40° C.
Sample injection volume: 20 μL (Sample concentration: 0.5% by mass tetrahydrofuran solution)
Detector: Differential refractive index meter (RI)

In the formula (1), each of m and l is independently 0 to 18; m is preferably 0 to 12, more preferably 0 to 6; l is preferably 0 to 12, more preferably 0 to 6.

In the formula (1), X represents a carbon-carbon unsaturated bond-containing organic group expressed by the following formula (2).

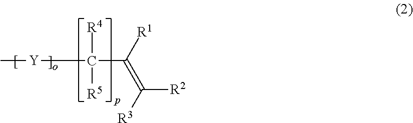

In the formula (2), each of R¹, R², R³, R⁴ and R⁵ independently represents a hydrogen atom, an alkyl group having 1 to 5 carbon atoms, or a (hetero)aryl group having 4 to 10 carbon atoms.

As the alkyl group having 1 to 5 carbon atoms which is represented by R¹, R², R³, R⁴ and R⁵, there may be listed, for example, a methyl group, an ethyl group, a n-propyl group, an isopropyl group, a n-butyl group, a sec-butyl group, an isobutyl group, a tert-butyl group, and a pentyl group.

As the (hetero)aryl group having 4 to 10 carbon atoms which is represented by R¹, R², R³, R⁴ and R⁵, there may be listed, for example, aryl groups having 6 to 10 carbon atoms, such as a phenyl group, a tolyl group, a xylyl group, and a naphthyl group; and heteroaryl groups having 4 to 10 carbon atoms such as a furyl group, a thienyl group, a pyridyl group, and an indolyl group.

As R¹, preferred is a hydrogen atom, a methyl group, or a phenyl group. As R² and R³, preferred is a hydrogen atom, a methyl group, or a phenyl group. As R⁴ and R⁵, preferred is a hydrogen atom or a methyl group.

In the formula (2), each of o and p is independently 0 or 1; o is preferably 0, and p is preferably 0.

In the formula (2), Y represents any one of the divalent organic groups expressed by the following structural formulae, and is preferably a phenylene group.

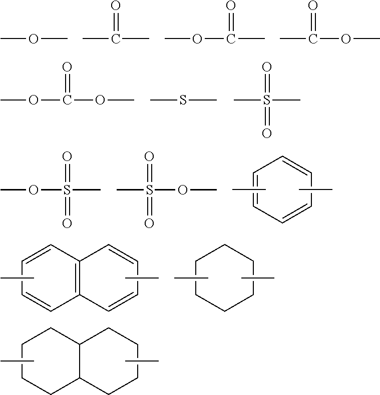

There are no particular restrictions on a method for producing the component (A); the component (A) may, for example, be efficiently produced by the following method.

As one example of the method for producing the modified imide compound of the formula (1) when n is 1 or larger, there may be employed a production method having:
a step A of synthesizing an amic acid with an acid anhydride represented by the following formula (3) and a diamine represented by the following formula (4), and then performing cyclodehydration; and
a step B subsequent to the step A, which is a step of synthesizing an amic acid with the reactant obtained in the step A and an unsaturated carbon-carbon bond-containing monoamine represented by the following formula (5), and then performing cyclodehydration.

Further, as one example of the method for producing the modified imide compound of the formula (1) when n is 0, there may be employed a production method having:
a step C of synthesizing an amic acid with the acid anhydride represented by the following formula (3) and the unsaturated carbon-carbon bond-containing monoamine represented by the following formula (5), and then performing cyclodehydration.

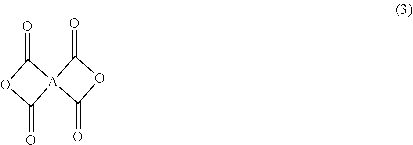

wherein A is defined as above in the formula (1).

H, N—B—NH₂ (4)
wherein B is defined as above in the formula (1).

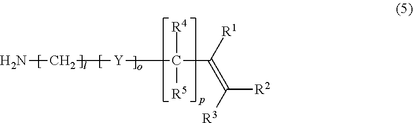

wherein R¹, R², R³, R^{4,} R⁵, Y, I, o and p are each defined as above in the formula (1).

The production method(s) have now been described. As a basic flow, the modified imide compound can be obtained either through the step A and then the step B: or merely through the step C. The step A is the step of synthesizing an amic acid with the acid anhydride (tetracarboxylic dianhydride) and the diamine, and then performing cyclodehydration; and the step B subsequent to the step A is the step of synthesizing an amic acid by reacting the unsaturated carbon-carbon bond-containing monoamine with the reactant obtained in the step A, and then finally performing cyclodehydration to block molecular chain ends with unsaturated carbon-carbon bond-containing organic groups. The step C is the step of synthesizing an amic acid by reacting the acid anhydride (tetracarboxylic dianhydride) and the unsaturated carbon-carbon bond-containing monoamine, and then finally performing cyclodehydration to block molecular chain ends with unsaturated carbon-carbon bond-containing organic groups.

In the above production method(s), the steps can be grouped into two categories which are the synthesis reaction of an amic acid; and the cyclodehydration reaction. These reactions are described in detail hereunder.

In the step A, an amic acid is at first synthesized by reacting a particular tetracarboxylic dianhydride with a particular diamine. This reaction usually proceeds in an organic solvent (e.g. non-polar solvent or high-boiling aprotic polar solvent) and at a temperature of room temperature (25° C.) to 100° C.

Next, the cyclodehydration reaction of the amic acid is performed in a way such that after reacting the amic acid at a temperature of 90 to 200° C., the cyclodehydration reaction is then caused to proceed while removing from the system a water produced as a by-product due to a condensation reaction. An organic solvent (e.g., non-polar solvent, high-boiling aprotic polar solvent) and/or an acid catalyst may also be added to promote the cyclodehydration reaction.

Examples of the organic solvent include toluene, xylene, anisole, biphenyl, naphthalene, N,N-dimethylformamide (DMF), and dimethylsulfoxide (DMSO). Any one kind of these organic solvents may be used alone, or two or more kinds of them may be used in combination. Further, examples of the acid catalyst include sulfuric acid, methanesulfonic acid, and trifluoromethanesulfonic acid. Any one kind of these acid catalysts may be used alone, or two or more kinds of them may be used in combination.

A molar ratio between the acid anhydride (tetracarboxylic dianhydride) represented by the formula (3) and the diamine represented by the formula (4) is preferably tetracarboxylic dianhydride/diamine=1.01 to 1.50/1.0, more preferably tetracarboxylic dianhydride/diamine=1.01 to 1.35/1.0. By combining the tetracarboxylic dianhydride and the diamine at this ratio, there can be synthesized, as a result, an imide compound with a carboxylic anhydride group being present at both ends thereof (the reactant obtained in the step A may simply be referred to as an imide compound hereafter).

Here, as for the tetracarboxylic dianhydride and diamine used in the step A, there may be used one kind each, or two or more kinds for one or both of these tetracarboxylic dianhydride and diamine.

In the step B, an amic acid is at first synthesized by reacting the imide compound obtained in the step A and the unsaturated carbon-carbon bond-containing monoamine at room temperature (25° C.) to 100° C., and cyclodehydration is then finally performed under a condition of 90 to 200° C. while removing from the system the water produced as a by-product, thereby blocking both molecular chain ends with unsaturated carbon-carbon bond-containing organic groups, thus obtaining the target modified imide compound.

A molar ratio between the imide compound and the unsaturated carbon-carbon bond-containing monoamine is preferably imide compound : unsaturated carbon-carbon bond-containing monoamine=1.0:1.6 to 2.5, more preferably 1.0:1.8 to 2.2.

Here, as for the unsaturated carbon-carbon bond-containing monoamine used in the step B, there may be used one or more kinds thereof.

In the step C, an amic acid is synthesized by reacting the particular tetracarboxylic dianhydride and unsaturated carbon-carbon bond-containing monoamine in an organic solvent (e.g., non-polar solvent or high-boiling aprotic polar solvent) at room temperature (25° C.) to 100° C. Next, the cyclodehydration reaction of the amic acid is performed in a way such that after reacting the amic acid at the temperature of 90 to 200° C., the cyclodehydration reaction is then caused to proceed while removing from the system the water produced as a by-product due to the condensation reaction, thereby blocking both molecular chain ends with unsaturated carbon-carbon bond-containing organic groups, thus obtaining the target modified imide compound. An organic solvent (e.g., non-polar solvent, high-boiling aprotic polar solvent) and/or an acid catalyst may also be added to promote the cyclodehydration reaction.

A molar ratio between the tetracarboxylic dianhydride and the unsaturated carbon-carbon bond-containing monoamine is preferably tetracarboxylic dianhydride : unsaturated carbon-carbon bond-containing monoamine=1.0:1.6 to 2.5, more preferably 1.0:1.8 to 2.2.

Here, as for the unsaturated carbon-carbon bond-containing monoamine used in the step C, there may be used one or more kinds thereof.

A method for purifying the modified imide compound obtained by the above method may be a conventional method, and it can also be directly used as a varnish.

### (B) Reaction Promotor

A component (B) used in the present invention is a reaction promotor.

The reaction promotor as the component (B) used in the present invention is added to initiate and promote the radical polymerization reaction or anionic polymerization reaction of the modified imide compound as the component (A).

There are no particular restrictions on the component (B) so long as it is cable of promoting such reaction; in terms of reaction mechanism, it is preferred that there be used a radical polymerization initiation catalyst such as an organic peroxide, or an anionic polymerization initiation catalyst containing at least one of nitrogen atom and phosphorus atom.

Examples of a radical polymerization initiation catalyst include dicumylperoxide, di-tert-butyl peroxide, 2,5-dimethyl-2,5-di-(tert-butylperoxy)hexane, 2,5-dimethyl-2,5-di(tert-butylperoxy)hexyne-3,1,3-bis(tert-butylperoxyisopropyl)benzene, 1,1-bis(tert-butylperoxy)-3,3,5-trimethylcyclohexane, n-butyl-4,4-bis(tert-butylperoxy)valerate, benzoyl peroxide, p-chlorobenzoyl peroxide, 2,4-dichlorobenzoyl peroxide, tert-butyl peroxybenzoate, tert-butyl peroxyisopropyl carbonate, diacetyl peroxide, lauroyl peroxide, and tert-butylcumyl peroxide.

Examples of an anionic polymerization initiation catalyst include imidazoles (e.g., 2-ethyl-4-methylimidazole), tertiary amines, quaternary ammonium salts, a boron trifluoride amine complex, organophosphines (e.g., triphenylphosphine), and an ion catalyst such as an organophosphonium salt.

As for the reaction promotor as the component (B), there may be used only one kind thereof, or two or more kinds thereof in combination.

The reaction promotor as the component (B) is preferably added in an amount of 0.01 to 10 parts by mass, particularly preferably 0.1 to 5 parts by mass, per 100 parts by mass of the component (A). If the amount of the component (B) is greater than these ranges, poor dielectric properties may be exhibited due to the fact that unreacted component (B) will remain. Meanwhile, if the amount of the component (B) is smaller than these ranges, curing may not proceed sufficiently, and dielectric properties and heat resistance may be impaired.

Further, it is not preferable when the amount of the component (B) added is outside the above ranges, because curing may take place either extremely slowly or quicky at the time of molding a heat-curable imide resin composition, and there may also be observed a poor balance between the heat resistance and moisture resistance of a cured product obtained.

In the heat-curable imide resin composition of the present invention, the component (A) is preferably contained in an amount of 5 to 99.99% by mass, more preferably 10 to 99.9% by mass, with respect to the total mass of the composition.

### Other Additives

If necessary, the heat-curable imide resin composition of the present invention may further contain various additives to the extent that the effects of the present invention will not be impaired. These additives are exemplified below.

Heat-curable resin having reactive group capable of reacting with carbon-carbon unsaturated bond-containing organic group

The present invention may further contain a heat-curable resin having reactive groups capable of reacting with carbon-carbon unsaturated bond-containing organic groups.

As a reactive group capable of reacting with a carbon-carbon unsaturated bond-containing organic group, there may be listed, for example, an epoxy group, a maleimide group, a hydroxyl group, an amino group, and a thiol group.

Further, no restrictions are imposed on the type of a heat-curable resin having such reactive groups. There may, for example, be employed various types of resins other than the component (A), such as heat-curable resins having carbon-carbon unsaturated bonds such as alkenyl groups as exemplified by allyl and vinyl groups, and (meth)acryl groups; an epoxy resin; a melamine resin; a phenolic resin; a melamine resin; a urea resin; a silicone resin; a modified polyphenylene ether resin; and a multifunctional thiol. As for the added heat-curable resin having reactive groups capable of reacting with carbon-carbon unsaturated bond-containing organic groups, there may be used one or more kinds thereof.

The heat-curable resin(s) having reactive groups capable of reacting with carbon-carbon unsaturated bond-containing organic groups is/are added in an amount of 0 to 30% by mass, preferably 0 to 20% by mass, with respect to a sum total of the component (A) and the heat-curable resin(s) having reactive groups capable of reacting with carbon-carbon unsaturated bond-containing organic groups.

### Inorganic Filler

In the present invention, there may further be added an inorganic filler if necessary. An inorganic filler is added to improve the strength and rigidity of the cured product of the heat-curable imide resin composition of the present invention, or adjust a thermal expansion coefficient and the dimension stability of the cured product. As such inorganic filler, there may be used those that are generally added to an epoxy resin composition or a silicone resin composition. There may be listed, for example, silicas such as a spherical silica, a molten silica and a crystalline silica; alumina; silicon nitride; aluminum nitride; boron nitride; barium sulfate; talc; clay; aluminum hydroxide; magnesium hydroxide: calcium carbonate; glass fibers; and glass particles. Further, for the sake of improving dielectric properties, there may also be used a fluorine-containing resin, a coating filler and/or hollow particles; and for the sake of, for example, imparting an electric conductivity, there may also be added electrically conductive fillers such as metal particles, metal-coated inorganic particles, carbon fibers and carbon nanotubes. As for the inorganic filler added, there may be used one or more kinds thereof.

There are no particular restrictions on the average particle size and shape of the inorganic filler; if molding an underfill material, a film, or a substrate, a spherical silica with an average particle size of 0.5 to 5 μm is particularly preferred. For adhesive and semiconductor encapsulation material purposes, a spherical silica with an average particle size of 3 to 45 μm is preferred. Here, the average particle size is a value obtained as a mass average value Dso (or median size) in a particle size distribution measurement conducted by a laser diffraction method.

There are no particular restrictions on the amount of the inorganic filler added; it is preferred that the inorganic filler be added in an amount of 5 to 3,000 parts by mass, more preferably 10 to 2,500 parts by mass, even more preferably 50 to 2,000 parts by mass, per 100 parts by mass of the component (A). When the amount of the inorganic filler is within these ranges, the function of the inorganic particles can be fully exerted while allowing the resin composition to retain its strength.

Further, for the sake of property improvement, it is preferred that the inorganic filler be one that has already been surface-treated with a silane coupling agent having organic groups capable of reacting with carbon-carbon unsaturated bond-containing organic groups. Examples of such silane coupling agent include an epoxy group-containing alkoxysilane, an amino group-containing alkoxysilane, a (meth)acryloyl group-containing alkoxysilane, and an alkenyl group-containing alkoxysilane.

As such silane coupling agent, preferred are a (meth)acryloyl group- and/or an amino group-containing alkoxysilane, specific examples of which include 3-methacryloxypropyltrimethoxysilane, 3-acryloxypropyltrimethoxysilane, N-phenyl-3-aminopropyltrimethoxysilane, N-2-(aminoethyl)-3-aminopropyltrimethoxysilane, and 3-aminopropyltrimethoxysilane.

### Others

In addition to the above additives, there may also be added, for example, a non-functional silicone oil, a thermoplastic resin, a thermoplastic elastomer, an organic synthetic rubber, a photosensitizer, a light stabilizer, a polymerization inhibitor, a flame retardant, a pigment, a dye, and an adhesion aid; and an ion-trapping agent for the purpose of improving electric properties.

### Production Method

As a method for producing the resin composition of the present invention, there may be employed, for example, a method where the components (A) and (B) as well as other additives that are added as needed are to be mixed using a planetary mixer or a stirrer.

The heat-curable imide resin composition of the present invention can also be treated as a varnish by being dissolved in an organic solvent. When in the form of a varnish, the composition can be easily turned into a film, and can be easily applied to or used to impregnate a glass cloth made of, for example, a low-dielectric glass such as an E glass and quartz glass, which makes it easier to produce a prepreg. There can be used any organic solvent so long as the component (A) can be dissolved therein.

As for the heat-curable imide resin composition of the present invention, an uncured resin sheet or an uncured resin film can be obtained by applying the varnish to a base material and then removing the solvent, and a cured resin sheet or a cured resin film can be obtained by further curing the uncured resin sheet or film. Examples of a method for producing the sheet and film include, but are not limited to those described below.

For example, after applying to a base material the heat-curable imide resin composition dissolved in the organic solvent, the organic solvent is eliminated by performing heating at a temperature of normally not lower than 80° C., preferably not lower than 100° C. for 0.5 to 5 hours, and a strong cured resin film with a flat surface can then be formed by further performing heating at a temperature of not lower than 130° C. preferably not lower than 150° C. for 0.5 to 10 hours. The temperature in the drying step for eliminating the organic solvent and the temperature in the subsequent heating and curing step may each be a constant temperature; it is preferred that these temperatures be raised in a step-wise manner. Thus, not only the organic solvent can be efficiently eliminated out of the composition, but the curing reaction of the resins can also take place efficiently. Examples of an application method may include those employing a spin coater, a slit coater, a sprayer, a dip coater and a bar coater; there are no particular restrictions on such method.

As a base material, there may be used those that are generally used, examples of which include polyolefin resins such as a polyethylene (PE) resin, a polypropylene (PP) resin and a polystyrene (PS) resin: and polyester resins such as a polyethylene terephthalate (PET) resin, a polybutylene terephthalate (PBT) resin and a polycarbonate (PC) resin. The surface of such base material may also be subjected to a mold release treatment. Further, there are no particular restrictions on the thickness of a coating layer; a thickness after distilling away the solvent is 1 to 200 μm, preferably 3 to 80 μm. A cover film may also be provided on such coating layer.

Instead, the uncured resin film (uncured resin sheet) or cured resin film (cured resin sheet) may also be produced by previously and preliminarily mixing the components, and then extruding the mixture into the shape of a sheet or a film with a melt-kneading machine.

If using the heat-curable imide resin composition of the present invention as a semiconductor encapsulation material, the components (A) and (B) as well as other components that are added as needed may be combined at given compounding ratios, and a mixer or the like may then be used to sufficiently uniformly mix them, after which the components may be melt-mixed using a heated roller, a kneader, an extruder or the like, followed by cooling the mixture so as to solidify the same before crushing it into an appropriate size(s). The resin composition obtained can be used as an encapsulation material.

Further, if using the heat-curable imide resin composition of the present invention as an adhesive, the components (A) and (B) as well as other components that are added as needed may be combined at given compounding ratios, and then mixed with a mixer such as a planetary mixer, followed by using a triple roll mill to further knead and mix them so as to improve dispersibility as appropriate. The resin composition obtained can be used as an adhesive.

As a general molding method using a semiconductor encapsulation material, there may be employed, for example, a transfer molding method or a compression molding method. In a transfer molding method, a transfer molding machine is used, where at a molding pressure of 5 to 20 N/mm², molding is carried out at a molding temperature of 120 to 190° C. for a molding time of 30 to 500 sec, preferably at a molding temperature of 150 to 185° C. for a molding time of 30 to 180 sec. Further, in a compression molding method, a compression molding machine is used, where molding is carried out at a molding temperature of 120 to 190° C. for a molding time of 30 to 600 sec, preferably at a molding temperature of 130 to 160° C. for a molding time of 120 to 300 sec. Furthermore, in either molding method, post curing may be performed at 150 to 225° C. for 0.5 to 20 hours.

### Prepreg

A prepreg of one embodiment of the present invention has the heat-curable imide resin composition of the present invention and a fiber base material. The heat-curable imide resin composition in the prepreg may be a semi-cured product of the resin composition. Here, a semi-cured product refers to a product of a state where the resin composition has been incompletely cured to the extent that the composition can actually be further cured. That is, the semi-cured product is a product of a state where the resin composition has been semi-cured, i.e., a B-staged product. Meanwhile, an uncured state may also be referred to as A-stage.

As described above, the fiber base material may, for example, be a low-dielectric glass such as an E glass and a quartz glass, or even an S glass or T glass: while there may be employed any type of glass, a quartz glass cloth having a low relative permittivity and dielectric tangent is preferred in terms of taking advantage of the properties of the heat-curable imide resin composition of the present invention. Here, the thickness of a generally used fiber base material is, for example, not smaller than 0.01 mm and not larger than 0.3 mm.

When producing the prepreg, it is preferred that the heat-curable imide resin composition be a resin varnish prepared in the form of a varnish, because the fiber base material as a base material for forming the prepreg is to be impregnated with the resin composition. Such resin composition in the form of a varnish (i.e., resin varnish) may, for example, be prepared as follows.

At first, components in the composition of the resin composition that are soluble in the organic solvent are to be added to the organic solvent to dissolve them. At that time, heating may also be performed if necessary. Next, components that are insoluble in the organic solvent, such as the inorganic filler used as needed are added, followed by using a ball mill, a bead mill, a planetary mixer, a roll mill or the like to disperse them until a given dispersed state has been reached, thereby obtaining the resin composition in the form of a varnish (i.e. resin varnish). There are no particular restrictions on the organic solvent used here so long as the organic solvent employed does not inhibit the curing reaction. Specific examples thereof include toluene, methyl ethyl ketone (MEK), xylene and anisole.

Next, after impregnating the fiber base material with the varnish-like resin composition (i.e., resin varnish) by, for example, dipping the fiber base material into the composition and/or applying the composition to the fiber base material, the fiber base material is then dried. If necessary, the fiber base material may be repeatedly impregnated several times. Further, at that time, it is also possible to repeat impregnation using multiple resin compositions with different compositions and concentrations, whereby the composition and impregnation amount can eventually be adjusted to desired ones.

The fiber base material impregnated with the resin composition (resin varnish) is to be heated under a desired heating condition(s), e.g., at 80 to 400° C. for 1 min to 2 hours. By heating, there can be obtained a prepreg having an uncured (A-staged) or semi-cured (B-staged) heat-curable imide resin composition.

### Substrate

The prepreg and a copper foil may be stacked, pressed and heated so as to be cured, whereby the cured product can then be used as a substrate.

There are no particular restrictions on a method for producing the substrate: for example, the substrate may be produced in such a manner that there are used 1 to 20, preferably 2 to 10 pieces of the abovementioned prepreg, followed by placing a copper foil on one or both surfaces thereof before curing them by pressing and heating.

There are no particular restrictions on the thickness of the copper foil; it is preferred that the copper foil have a thickness of 3 to 70 μm, more preferably 10 to 50 μm, even more preferably 15 to 40 μm. If the thickness of the copper foil is within these ranges, there can be molded a multi-layered substrate possessing a high reliability.

There are no particular restrictions on a condition(s) for molding the substrate; for example, molding may be performed at a temperature of 100 to 400° C. and a pressure of 1 to 100 MPa for a heating period of 0.1 to 4 hours, using a multistage pressing machine, a multistage vacuum pressing machine, a continuous molding machine, an autoclave molding machine or the like. Further, the substrate can also be molded by combining and molding the prepreg(s) of the present invention, a copper foil, and a wiring board for inner layers.

### WORKING EXAMPLES

The present invention is described in detail hereunder with reference to synthesis, working and comparative examples; the present invention shall not be limited to the following working examples. Here, in each example, “room temperature” refers to 25° C.

### Synthesis Example 1

### Production of Modified Imide Compound 1, Reaction Formula 1

An amic acid was synthesized by adding 41.05 g (0.100 mol) of 2,2-bis[4-(4-aminophenoxy)phenyl]propane, 54.65 g (0.105 mol) of 4,4′-(4,4′-isopropylidenediphenoxy)bis(phthalic anhydride) and 216 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby synthesizing a polyimide compound.

Next, 0.63 g (0.011 mol, amount equivalent to 2.2 mol per 1 mol of the above polyimide compound) of allylamine was added to the flask containing the polyimide compound solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target modified imide compound 1 (number average molecular weight: 42,000) represented by a formula (6) of the following reaction formula I as a yellow varnish (containing 71% by mass of anisole).

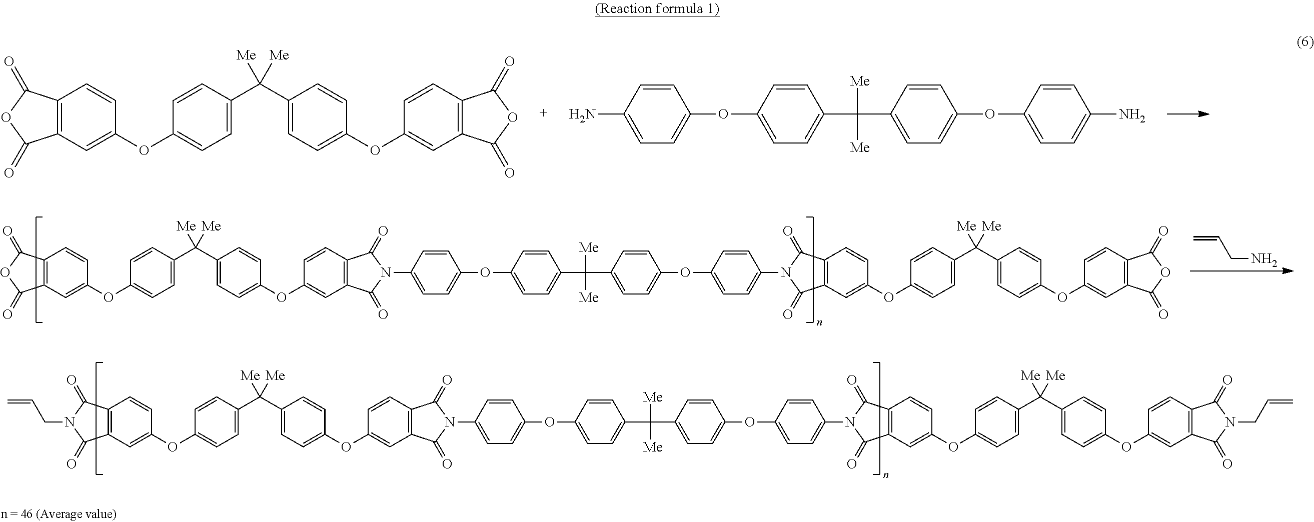

### Synthesis Example 2

### Production of Modified Imide Compound 2, Reaction Formula 2

An amic acid was synthesized by adding 41.05 g (0.100 mol) of 2,2-bis[4-(4-aminophenoxy)phenyl]propane, 54.65 g (0.105 mol) of 4,4 -(4.4′-isopropylidenediphenoxy)bis(phthalic anhydride) and 216 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby synthesizing a polyimide compound.

Next, 0.78 g (0.011 mol, amount equivalent to 2.2 mol per 1 mol of the above polyimide compound) of 3-butene-1-amine was added to the flask containing the polyimide compound solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target modified imide compound 2 (number average molecular weight: 33,000) represented by a formula (7) of the following reaction formula 2 as a brown varnish (containing 66% by mass of anisole).

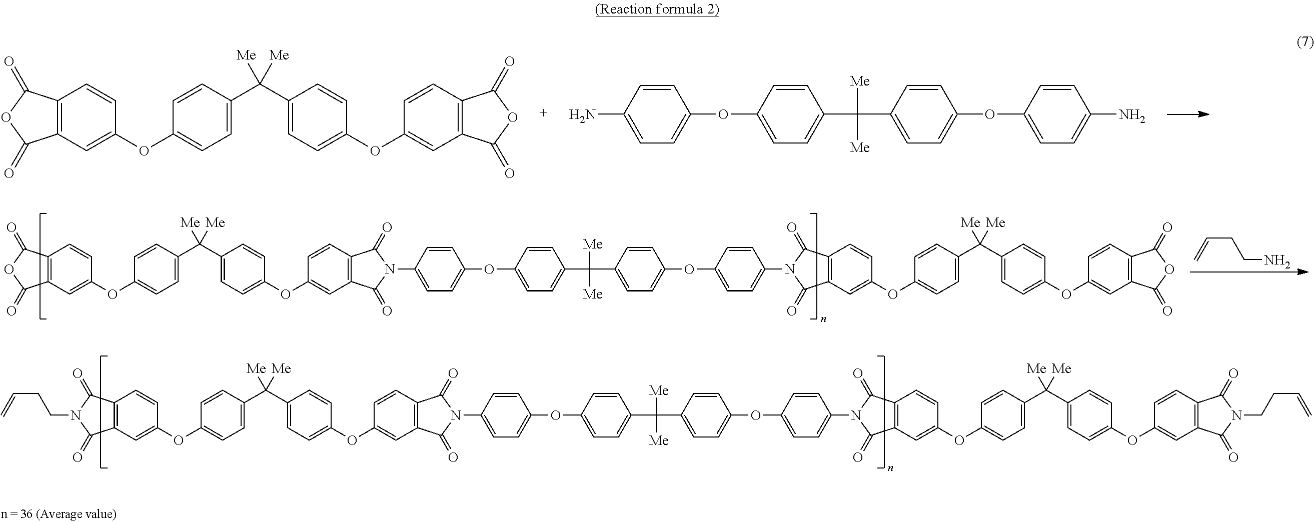

### Synthesis Example 3

### Production of Modified Imide Compound 3, Reaction Formula 3

An amic acid was synthesized by adding 25.17 g (50.0 mmol) of 9,9-bis[4-(4-aminophenoxy)phenyl]fluorene, 33.74 g (52.5 mmol) of 9,9-bis[4-(3,4-dicarboxyphenoxy)phenyl]fluorene dianhydride and 172 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby synthesizing a polyimide compound.

Next, 0.31 g (5.5 mmol, amount equivalent to 2.2 mol per 1 mol of the above polyimide compound) of allylamine was added to the flask containing the polyimide compound solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target modified imide compound 3 (number average molecular weight: 22,000) represented by a formula (8) of the following reaction formula 3 as a yellow varnish (containing 72% by mass of anisole).

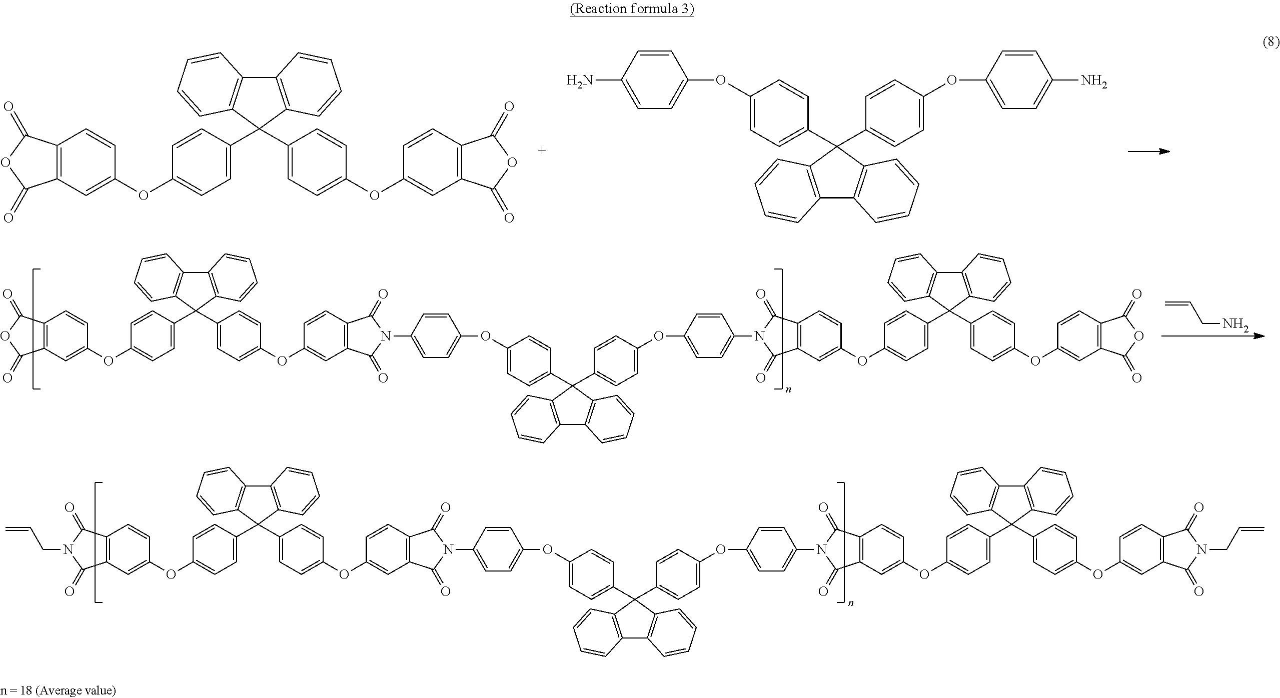

### Synthesis Example 4

### Production of Modified Imide Compound 4, Reaction Formula 4

An amic acid was synthesized by adding 20.53 g (50.0 mmol) of 2,2-bis[4-(4-aminophenoxy)phenyl]propane, 27.33 g (52.5 mmol) of 4,4′-(4,4′-isopropylidenediphenoxy)bis(phthalic anhydride) and 140 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby synthesizing a polyimide compound.

Next, 0.73 g (5.5 mmol, amount equivalent to 2.2 mol per 1 mol of the above polyimide compound) of 4-vinylbenzylamine was added to the flask containing the polyimide compound solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target modified imide compound 4 (number average molecular weight: 28,000) represented by a formula (9) of the following reaction formula 4 as a brown varnish (containing 77% by mass of anisole).

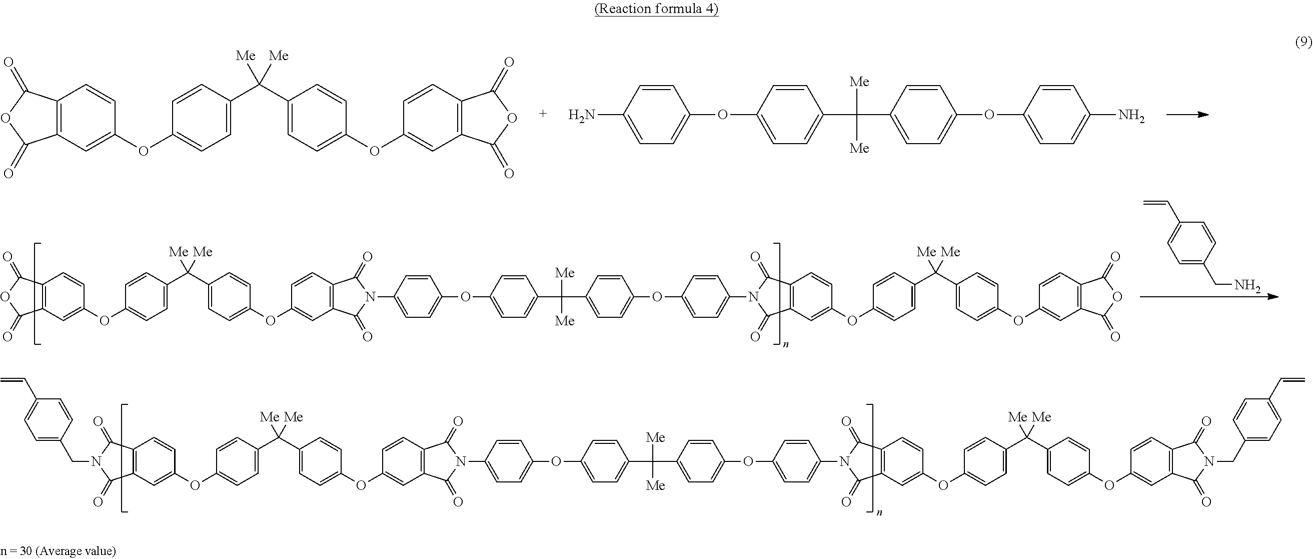

### Synthesis Example 5

### Production of Modified Imide Compound 5, Reaction Formula 5

An amic acid was synthesized by adding 20.53 g (50.0 mmol) of 2,2-bis[4-(4-aminophenoxy)phenyl]propane, 27.33 (52.5 mmol) of 4,4′-(4,4′-isopropylidenediphenoxy)bis(phthalic anhydride) and 139 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C. where stirring was performed for 5 hours while distilling away water generated as a by-product, thereby synthesizing a polyimide compound.

Next, 0.39 g (5.5 mmol, amount equivalent to 2.2 mol per 1 mol of the above polyimide compound) of 2-methylallylamine was added to the flask containing the polyimide compound solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target modified imide compound 5 (number average molecular weight: 38,000) represented by a formula (10) of the following reaction formula 5 as a brown varnish (containing 76% by mass of anisole).

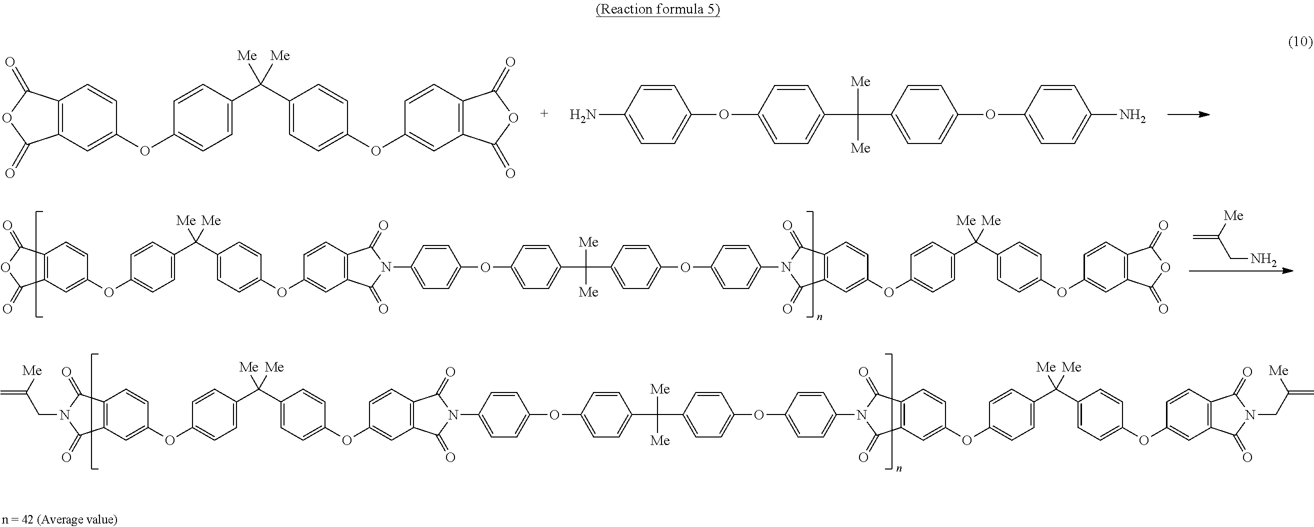

### Comparative Synthesis Example 1

### Production of Bismaleimide Compound 1, Reaction Formula 6

An amic acid was synthesized by adding 42.93 g (0.105 mol) of 2,2-bis[4-(4-aminophenoxy)phenyl]propane, 52.05 g (0.100 mol) of 4,4°-(4,4′-isopropylidenediphenoxy)bis(phthalic anhydride) and 171 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby synthesizing a polyimide compound.

Next, 1.08 g (0.011 mol) of maleic anhydride was added to the flask containing the polyimide solution that had been cooled to room temperature, where the polyimide compound solution was stirred at room temperature for an hour to synthesize an amic acid. Next, the temperature was directly raised to 150° C., where stirring was performed for 6 hours while distilling away water generated as a by-product, thereby obtaining a target bismaleimide compound 1 (number average molecular weight: 20,000) represented by a formula (11) of the following reaction formula 6 as a light yellow varnish (containing 65% by mass of anisole).

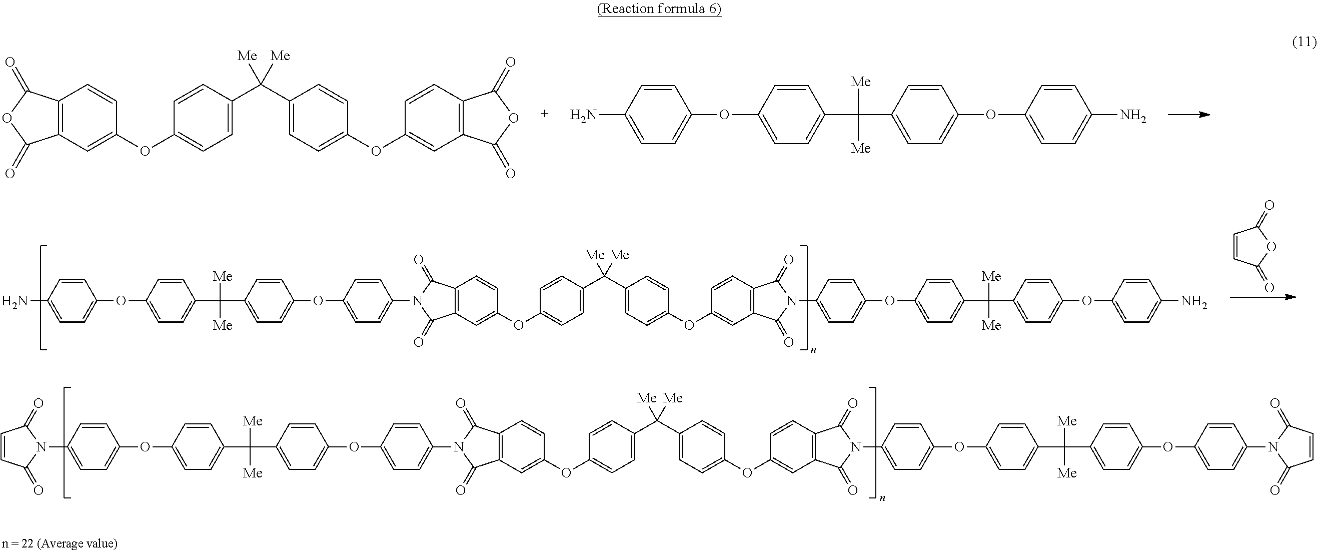

### Synthesis Example 6

### Production of Modified Imide Compound 6, Reaction Formula 7

An amic acid was synthesized by adding 12.56 g (0.22 mol) of allylamine, 52.05 g (0.10 mol) of 4,4′-(4,4′-isopropylidenediphenoxy)bis(phthalic anhydride) and 142 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby obtaining a varnish of a modified imide compound 6. After delivering the varnish obtained by drops into 1,000 g of heptane, a precipitate was then collected by a filtration operation. As a result of drying the solid thus obtained, there was produced a target modified imide compound 6 (number average molecular weight: 480) represented by a formula (12) of the following reaction formula 7 as a brown solid.

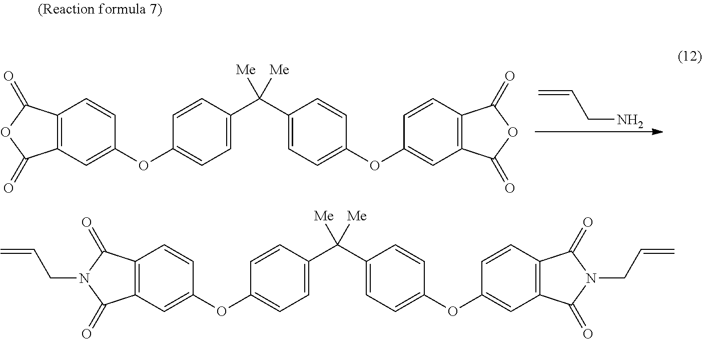

### Synthesis Example 7

### Production of Modified Imide Compound 7, Reaction Formula 8

An amic acid was synthesized by adding 12.56 g (0.22 mol) of allylamine, 62.84 g (0.10 mol) of 4,4′-(4,4′-hexafluoroisopropylidenediphenoxy)bis(phthalic anhydride) and 168 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby obtaining a varnish of a modified imide compound 7. After delivering the varnish obtained by drops into 1,000 g of heptane, a precipitate was then collected by a filtration operation. As a result of drying the solid thus obtained, there was produced a target modified imide compound 7 (number average molecular weight: 720) represented by a formula (13) of the following reaction formula 8 as a white solid.

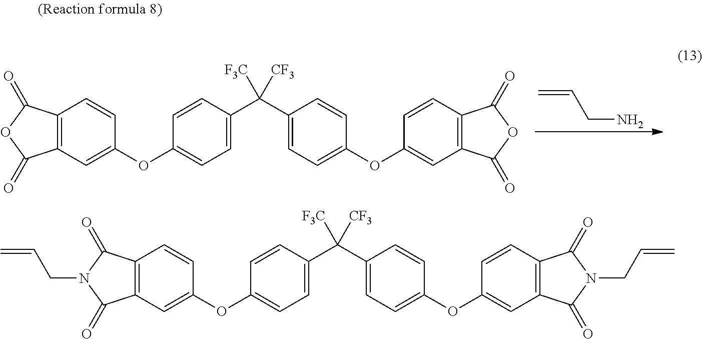

### Synthesis Example 8

### Production of Modified Imide Compound 8, Reaction Formula 9

An amic acid was synthesized by adding 12.56 g (0.22 mol) of allylamine, 31.02 g (0.10 mol) of oxydiphthalic anhydride and 93 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby obtaining a varnish of a modified imide compound 8. After delivering the varnish obtained by drops into 1,000 g of heptane, a precipitate was then collected by a filtration operation. As a result of drying the solid thus obtained, there was produced a target modified imide compound 8 (number average molecular weight: 240) represented by a formula (14) of the following reaction formula 9 as a white solid.

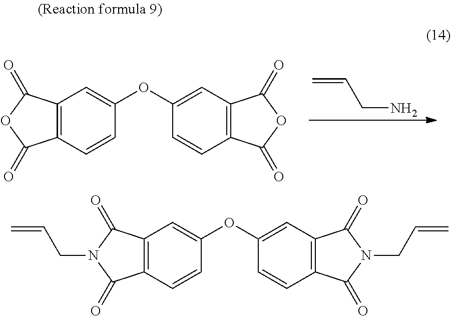

### Synthesis Example 9

### Production of Modified Imide Compound 9, Reaction Formula 10

An amic acid was synthesized by adding 12.56 g (0.22 mol) of allylamine, 44.42 g (0.10 mol) of 4,4′-(hexafluoroisopropylidene)diphthalic anhydride and 125 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby obtaining a varnish of a modified imide compound 9. After delivering the varnish obtained by drops into 1,000 g of heptane, a precipitate was then collected by a filtration operation. As a result of drying the solid thus obtained, there was produced a target modified imide compound 9 (number average molecular weight: 430) represented by a formula (15) of the following reaction formula 10 as a white solid.

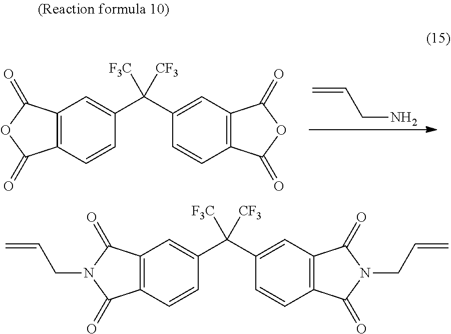

### Synthesis Example 10

### Production of Modified Imide Compound 10, Reaction Formula 11

An amic acid was synthesized by adding 12.56 g (0.22 mol) of allylamine, 64.26 g (0.10 mol) of 9,9″-bis[4-(3,4-dicarboxyphenoxy)phenyl]fluorene dianhydride and 171 g of anisole to a 500 mL glass three-necked flask equipped with a stirrer, a Dean-Stark apparatus, a cooling condenser and a thermometer, and then by stirring them at 70° C. for 2 hours. Next, the temperature was directly raised to 150° C., where stirring was performed for 5 hours while distilling away water generated as a by-product, thereby obtaining a varnish of a modified imide compound 10. After delivering the varnish obtained by drops into 1,000 g of heptane, a precipitate was then collected by a filtration operation. As a result of drying the solid thus obtained, there was produced a target modified imide compound 10 (number average molecular weight: 690) represented by a formula (16) of the following reaction formula 11 as a white solid.

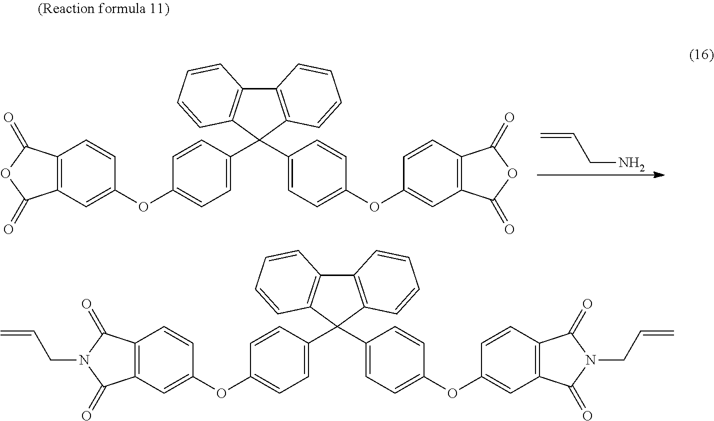

### Comparative Example 2

### Bismaleimide Compound 2

2,2-bis[4-(4-maleimidephenoxy)phenyl]propane (BMI-4000 by Daiwakasei Industry Co., LTD., number average molecular weight: 620)

### Working Examples 1 to 5; Comparative Example 1

The varnishes of the modified imide compounds 1 to 5 synthesized in the synthesis examples 1 to 5 and the varnish of the bismaleimide compound I synthesized in the comparative synthesis example I were each adjusted to have a resin content of an amount of 50 g, where 1 g of dicumylperoxide was then dissolved therein to obtain a resin composition varnish. A roller coater was then used to apply each resin composition varnish thus prepared to a 100 μm-thick AFLEX film so that the thickness of the composition after drying would be 30 μm, followed by drying them at 80° C. for 15 min to obtain an uncured resin film. Next, post curing was performed at 180° C. for two hours to produce a film-shaped sample for dielectric property evaluation. Later, the AFLEX film was removed before measurement.

### Working Examples 6 to 10; Comparative Example 2

Here, 1 g of dicumylperoxide was added to and mixed with 50 g of each of the modified imide compounds 6 to 10 synthesized in the synthesis examples 6 to 10 and the bismaleimide compound 2 to obtain a resin composition. Each resin composition thus prepared was then pressed at 180° C. for 10 min so that the composition after drying would be 200 μm, thereby obtaining an uncured resin film. Next, post curing was performed at 180° C. for two hours to produce a film-shaped sample for dielectric property evaluation.

### Dielectric Property (Dielectric Tangent)

A network analyzer (E5063-2D5 by Keysight Technologies) and a stripline (by KEYCOM Corporation) were connected to the film-shaped sample for dielectric property evaluation produced as above to measure a dielectric tangent of the film at a frequency of 10 GHz.

### Glass-Transition Temperature (Tg)

The glass-transition temperature of the film-shaped sample for dielectric property evaluation produced as above was measured using TMA8140C (by Rigaku Corporation) or DMA-800 (by TA Instruments).

TABLE 1

| | Working | Working | Working | Working | Working | Comparative |
|---|---|---|---|---|---|---|
| | example 1 | example 2 | example 3 | example 4 | example 5 | example 1 |
| Resin | Modified | Modified | Modified | Modified | Modified | Bismaleimide |
| | imide | imide | imide | inside | imide | compound 1 |
| | compound 1 | compound 2 | compound 3 | compound 4 | compound 5 | |
| Dielectric tangent | 0.0036 | 0.0033 | 0.0046 | 0.0041 | 0.0038 | 0.0046 |
| (10 GHz) | | | | | | |
| Glass-transition | 188 | 184 | 263 | 184 | 180 | 184 |
| temperature(TMA)[° C.] | | | | | | |

As compared to the resin composition of the bismaleimide compound 1 synthesized in the comparative synthesis example 1, the resin compositions of the modified imide compounds 1 to 5 were confirmed to have improved dielectric properties, i.e., small dielectric tangents while maintaining high glass-transition temperatures.

TABLE 2

| | Working | Working | Working | Working | Working | Comparativa |
|---|---|---|---|---|---|---|
| | example 6 | example 7 | example 8 | example 9 | example 10 | example 2 |
| Resin | Modified | Modified | Modified | Modified | Modified | Bismaleimide |
| | imide | imide | imide | imide | imide | compound 2 |
| | compound 6 | compound 7 | compound8 | compound 9 | compound 10 | |
| Dielectric tangent | 0.0023 | 0.0026 | 0.0018 | 0.0022 | 0.0044 | 0.0045 |
| (10 GHz) | | | | | | |
| Glass-transition | 171 | 204 | 226 | 256 | 237 | 201 |
| temperature(DMA)[° C.] | | | | | | |

As compared to the resin composition of the bismaleimide compound 2, the resin compositions of the modified imide compounds 6 to 10 were confirmed to have improved dielectric properties, i.e., small dielectric tangents while maintaining high glass-transition temperatures.

### Working Examples 11 to 15; Comparative Example 3

Here, 100 g of each of the modified imide compounds 1 to 5 prepared in the synthesis examples 1 to 5 and the bismaleimide compound 1, 2 g of dicumylperoxide, 133 g of a silica dispersion slurry (5SV-CT1 by ADMATECHS COMPANY LIMITED, average particle size 0.5 um, solid concentration 75% by mass, solvent: toluene), and 200 g of anisole were mixed to obtain a varnish.

### Production Method of Prepreg

The varnish obtained was used to impregnate a quartz glass cloth (thickness 90 μm, SQX2116 by Shin-Etsu Chemical Co., Ltd.), followed by performing heating at 120° C. for 6 min to volatilize the solvent, thereby obtaining a prepreg (resin composition impregnation amount: 50% by mass).

### Production Method of Copper-Clad Laminate

An 18 μm-thick copper foil (surface roughness: 0.6 μm) was put on both surfaces of the prepreg obtained as above, followed by heating them at 180° C. for an hour while applying a pressure of 1.7 MPa thereon, thereby producing a copper-clad laminate.

### Dielectric Property (Dielectric Tangent), Glass-Transition Temperature (Tg)

After removing the copper foils on both surfaces of the above copper-clad laminate via etching. the network analyzer (E5063-2D5 by Keysight Technologies) and the stripline (by KEYCOM Corporation) were connected to measure the prepreg's dielectric tangent at the frequency of 10 GHz. Further, the glass-transition temperature was measured using DMA-800 (by TA Instruments). The results are shown in Table 3.

TABLE 3

| | Working | Working | Working | Working | Working | Comparative |
|---|---|---|---|---|---|---|
| | example 11 | example 12 | example 13 | example 14 | example 15 | example 3 |
| Resin | Modified | Modified | Modified | Modified | Modified | Bismaleimide |
| | imide | imide | imide | imlide | imide | compound 1 |
| | compound 1 | compound 2 | compound 3 | compound 4 | compound 5 | |
| Dielectric tangent | 0.0031 | 0.0030 | 0.0039 | 0.0035 | 0.0032 | 0.0039 |
| (10 GHz) | | | | | | |
| Glass-transition | 200 | 196 | 280 | 196 | 192 | 196 |
| temperature(DMA)[° C.] | | | | | | |

As shown in Table 3, the heat-curable imide resin composition of the present invention was confirmed to be superior in dielectric property and heat resistance.

### Production Method of Printed-Wiring Board

Here, 10 pieces of the prepreg obtained as above and 11 pieces of the 18 μm-thick copper foil (surface roughness: 0.6 μm) were sequentially stacked together, followed by heating them at 180° C. for an hour while applying a pressure of 1.7 MPa thereon, thereby producing a copper-clad laminate. A 30 μm-thick dry resist film (NIT430E by Nikko-Materials Co., Ltd.) was then attached to this copper-clad laminate via vacuum lamination that was conducted at 0.4 MPa and 80° C. for 60 sec. Next, a mask with a circuit pattern formed thereon was brought into contact therewith, followed by performing UV irradiation from above, and then conducting development with a sodium hydrogen carbonate aqueous solution. Later, etching was carried out by being dipped into an etching solution (H-1000A by Sunhayato Corp), and washing was then performed using a sodium hydroxide aqueous solution, thereby obtaining a printed-wiring board with a circuit formed thereon.

### INDUSTRIAL APPLICABILITY

In the case of the heat-curable imide resin composition of the present invention, when molded into the shape of a film or a substrate, there can be provided a cured product having an excellent dielectric property as indicated by a small dielectric tangent at a high frequency, and also having an excellent heat resistance as indicated by a high Tg. The heat-curable imide resin composition of the present invention is particularly suitable for use in, for example, multi-layered printed wiring boards installed in electronic devices for high-frequency band uses that require insulating materials with superior dielectric properties.

What is claimed is:

1. A heat-curable imide resin composition comprising:
(A) a modified imide compound represented by the following formula (1) 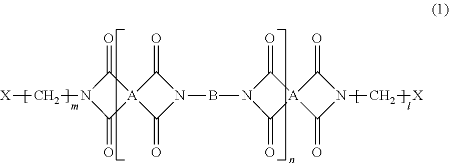
wherein A independently represents a tetravalent organic group having 4 to 200 carbon atoms; B independently represents a divalent organic group having 2 to 200 carbon atoms; n is 0 to 100; each of m and l is independently 0 to 18; X independently represents a carbon-carbon unsaturated bond-containing organic group expressed by the following formula (2) 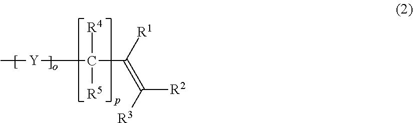
wherein each of R¹, R², R³, R⁴ and R⁵ independently represents a hydrogen atom, an alkyl group having 1 to 5 carbon atoms, or a (hetero)aryl group having 4 to 10 carbon atoms; each of o and p is independently 0 or 1; Y represents any one of the divalent organic groups expressed by the following structural formulae 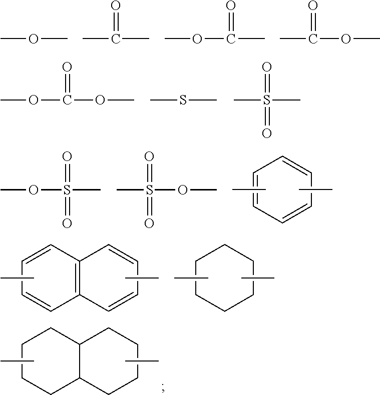
and
(B) a reaction promotor

2. The heat-curable imide resin composition according to claim 1, wherein A in the formula (1) is any one of the tetravalent organic groups represented by the following structural formulae 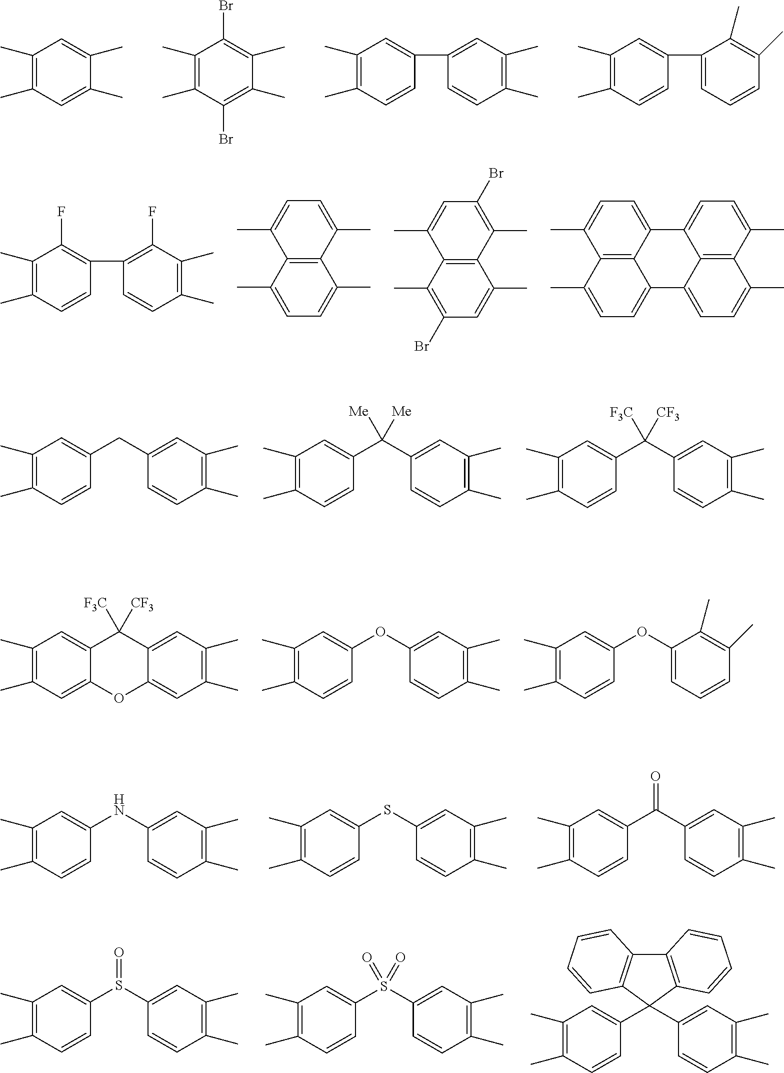 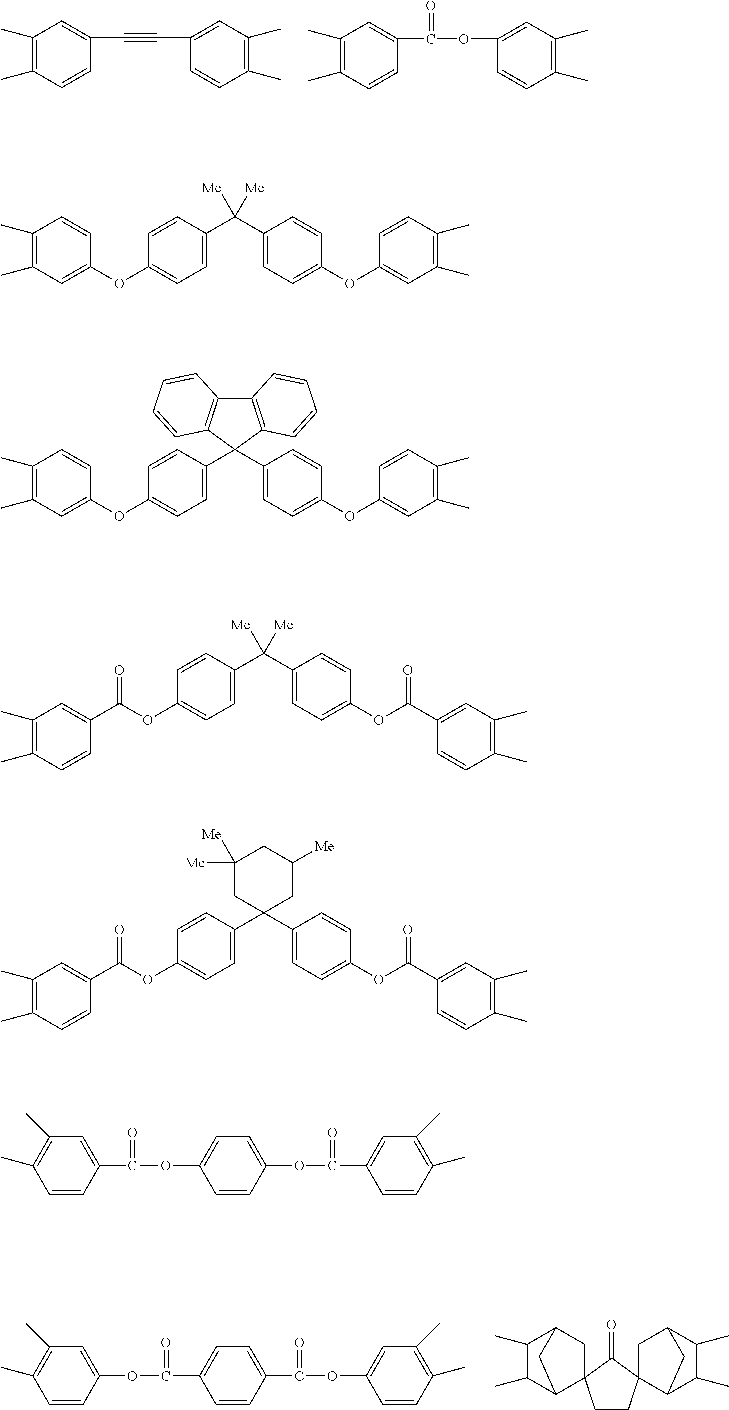 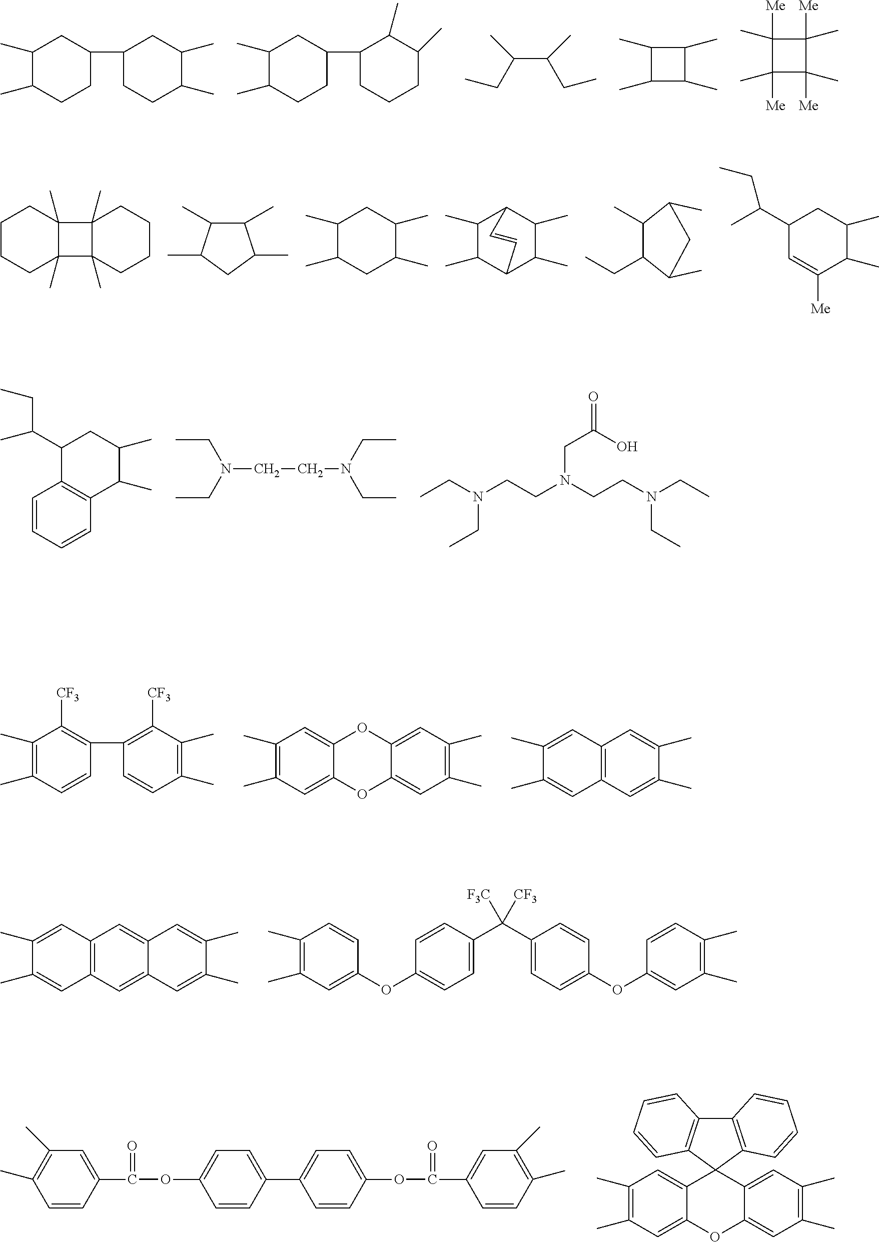 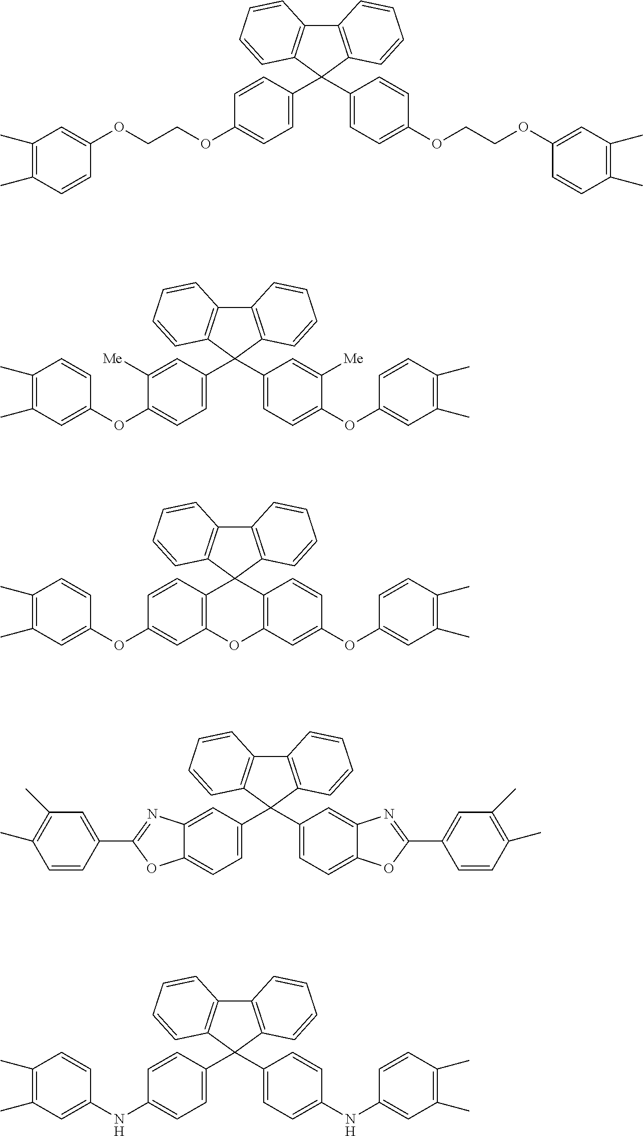 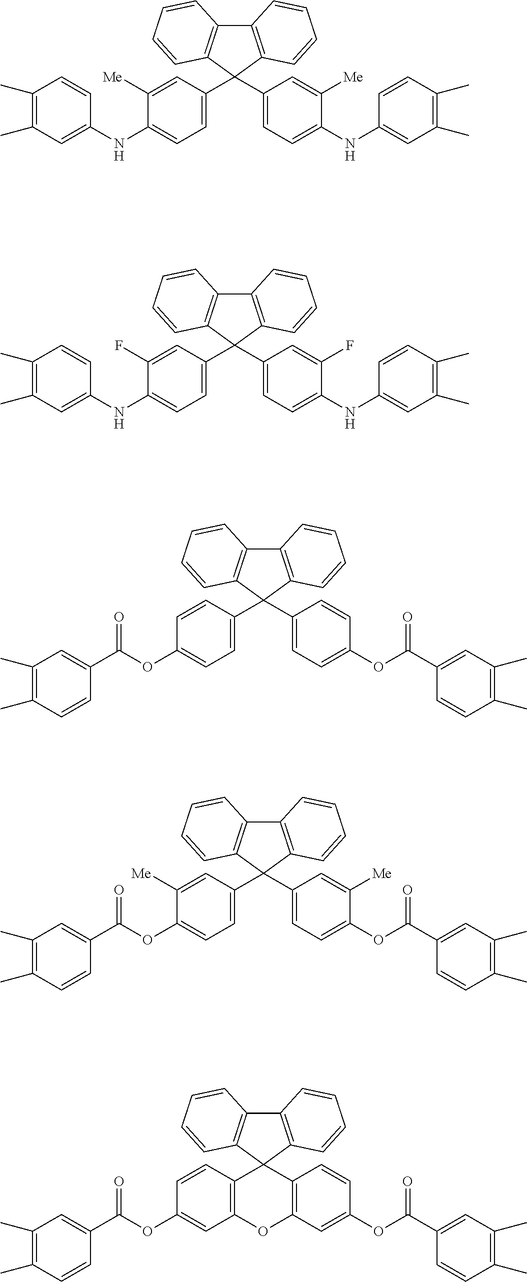 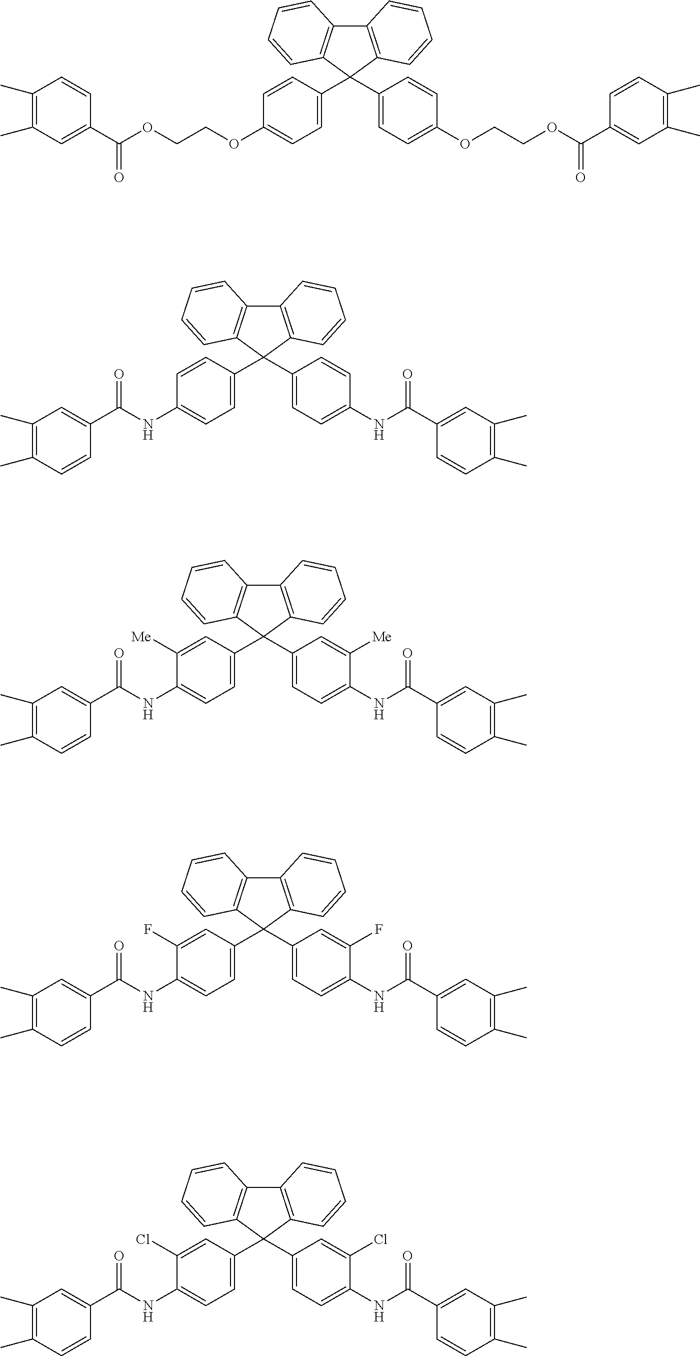 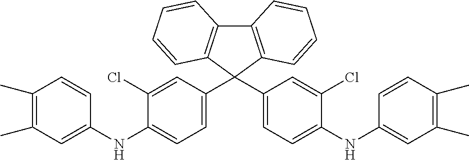
wherein bonds that are yet unbonded to substituent groups are to be bonded to carbonyl carbons forming cyclic imide structures in the formula (1).

3. The heat-curable imide resin composition according to claim 1, wherein the modified imide compound of the formula (1) has a number average molecular weight of 200 to 80,000.

4. The heat-curable imide resin composition according to claim 1, wherein the reaction promotor as the component (B) is a radical polymerization initiation catalyst, or an anionic polymerization initiation catalyst containing at least one of nitrogen atom and phosphorus atom.

5. An uncured resin film comprised of the heat-curable imide resin composition according to claim 1.

6. A cured resin film comprised of a cured product of the heat-curable imide resin composition according to claim 1.

7. A prepreg comprising the heat-curable imide resin composition according to claim 1 and a fiber base material.

8. A substrate comprising the heat-curable imide resin composition according to claim 1.

9. An adhesive comprised of the heat-curable imide resin composition according to claim 1.

10. A semiconductor encapsulation material comprised of the heat-curable imide resin composition according to claim 1.
